(19) United States
(12) Patent Application Publication
(10) Pub. No.: US 2025/0072176 A1
(43) Pub. Date: Feb. 27, 2025

(54) DISPLAY DEVICE

(71) Applicant: Samsung Display Co., LTD., Yongin-si (KR)

(72) Inventors: Kangyoung LEE, Yongin-si (KR); Jinwoo CHOI, Yongin-si (KR); Hyungil JEON, Yongin-si (KR); Changil TAE, Yongin-si (KR)

(21) Appl. No.: 18/811,420

(22) Filed: Aug. 21, 2024

(30) Foreign Application Priority Data
Aug. 23, 2023 (KR) 10-2023-0110764

(51) Int. Cl. H01L 33/50; H01L 25/16; H01L 33/22

(52) U.S. Cl. CPC H01L 33/505; H01L 25/167; H01L 33/22

(57) ABSTRACT

A display device includes: a substrate including a display area and a non-display area outside the display area; and a plurality of light-emitting diodes arranged in the display area, where each of the plurality of the light-emitting diodes has a double porous layer structure including a first porous layer and a second porous layer disposed below the first porous layer, the first porous layer defines a first pore therein extending in a direction perpendicular to a major surface of the substrate, and the second porous layer defines a second pore therein extending in a randomly variable direction.

This application claims priority to Korean Patent Application No. 10-2023-0110764, filed on Aug. 23, 2023, and all the benefits accruing therefrom under 35 U.S.C. § 119, the content of which in its entirety is herein incorporated by reference.

### BACKGROUND

### 1. Field

One or more embodiments relate to the structure of a display device.

### 2. Description of the Related Art

With the development of display devices that visually display electrical signals, various display devices having excellent characteristics, such as thinness, weight reduction, and low power consumption, have been introduced. For example, flexible display devices that can be folded or rolled into a roll shape have been introduced. Recently, research and development of stretchable display devices that can change into various forms are actively underway.

### SUMMARY

One or more embodiments include a display device with improved light conversion efficiency and light extraction efficiency. Embodiments set forth herein are examples, and the scope of the disclosure is not limited thereby.

Additional aspects will be set forth in part in the description which follows and, in part, will be apparent from the description, or may be learned by practice of the presented embodiments of the disclosure.

According to one or more embodiments, a display device includes: a substrate including a display area and a non-display area outside the display area; and a plurality of light-emitting diodes arranged in the display area, where each of the plurality of light-emitting diodes has a double porous layer structure including a first porous layer and a second porous layer disposed below the first porous layer, the first porous layer defines a first pore therein extending in a direction perpendicular to a major surface of the substrate, and the second porous layer defines a second pore therein extending in a randomly variable direction.

Quantum dots may be arranged within the first pore and the second pore.

The display device may further include a base resin arranged in the first pore and the second pore, wherein the quantum dots are dispersedly arranged in the base resin.

The display area may include a first sub-pixel for emitting red light, a second sub-pixel for emitting green light, and a third sub-pixel for emitting blue light, the quantum dots may be arranged in a light-emitting diode of the first sub-pixel and a light-emitting diode of the second sub-pixel, and the plurality of light-emitting diodes may include the light-emitting diode of the first sub-pixel and the light-emitting diode of the second sub-pixel.

The first pore and the second pore arranged in the third sub-pixel may be filled with the base resin without the quantum dots.

The first pore and the second pore may be extended and connected to each other.

The first pore may have a cylindrical shape.

The second pore may have a spiral cylindrical shape.

A planar diameter of each of the first pore and the second pore may be about 100 nanometers (nm) to about 200 nm.

In the direction perpendicular to a major surface of the substrate, a thickness of the first porous layer and a thickness of the second porous layer may be equal to each other.

In the direction perpendicular to a major surface of the substrate, a thickness of the first porous layer may be greater than a thickness of the second porous layer.

In the direction perpendicular to a major surface of the substrate, a thickness of the second porous layer may be greater than a thickness of the first porous layer.

Each of the plurality of light-emitting diode may further include: a first semiconductor layer doped with a p-type dopant, a second semiconductor layer doped with an n-type dopant, and an intermediate layer disposed between the first semiconductor layer and the second semiconductor layer, where the first porous layer and the second porous layer may be included in the second semiconductor layer.

The first porous layer may have a structure in which the first pore is defined in a material constituting the second semiconductor layer, and the second porous layer may have a structure in which the second pore is defined in a material constituting the second semiconductor layer.

The material constituting the second semiconductor layer may include a semiconductor material having a composition formula InₓAl_{y}Ga_{1-x-y}N (0≤x≤1, 0≤y≤1, 0≤x+y≤1).

The second semiconductor layer may further include a base layer disposed between the intermediate layer and the second porous layer, wherein the base layer may have a non-porous structure.

Each of the first porous layer and the second porous layer may have a thickness of about 2 micrometers (μm) to about 7 μm.

The base layer may have a thickness of about 0.3 μm to about 0.5 μm.

Each of the plurality of light-emitting diodes may further include a sub-pixel electrode electrically connected to the first semiconductor layer, and an opposite electrode electrically connected to the second semiconductor layer, wherein the sub-pixel electrode may be connected to a pixel circuit arranged in the display area, and the opposite electrode may be electrically connected to a voltage line for receiving a low-potential voltage.

The display device may further include: a light-blocking layer disposed above each of the plurality of the light-emitting diodes and defining a light-blocking layer opening therein overlapping the light-emitting diode, and an overcoat layer disposed on the light-blocking layer.

The overcoat layer may fill the light-blocking layer opening.

The display device may further include a color filter layer, which fills the light-blocking layer opening, where the overcoat layer may cover the light-blocking layer and the color filter layer.

The display device may further include an encapsulation layer disposed between the light-blocking layer and each of the plurality of light-emitting diodes.

The display device may further include island portions arranged in the display area and spaced apart from each other along rows and columns, and bridge portions connecting adjacent island portions among the island portions to each other, where each of the island portions may include at least one light-emitting diode of the plurality of light-emitting diodes.

The bridge portions may each have a serpentine shape.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically showing a display device according to an embodiment;

FIGS. 2A and 2B are perspective views showing the display device of FIG. 1 stretched in a first direction;

FIG. 2C is a perspective view showing the display device of FIG. 1 stretched in a second direction;

FIG. 2D is a perspective view showing the display device of FIG. 1 stretched in the first and second directions;

FIG. 2E is a perspective view showing the display device of FIG. 1 stretched in a third direction;

FIG. 3 is a plan view schematically showing a display device according to an embodiment;

FIG. 4A is an enlarged plan view of an area IV of FIG. 3 as part of a display device according to an embodiment;

FIG. 4B is an enlarged plan view of an area IV of FIG. 3 as part of a display device according to an embodiment;

FIG. 4C is an enlarged plan view of an area IV of FIG. 3 as part of a display device according to an embodiment;

FIG. 5 is a cross-sectional view schematically showing a first island portion and a first bridge portion disposed in a display area of a stretchable display device according to an embodiment;

FIGS. 6A to 6C are equivalent circuit diagrams of a sub-pixel of a stretchable display device according to an embodiment;

FIG. 7 is a plan view schematically showing a portion of a display device according to an embodiment;

FIG. 8 is a cross-sectional view schematically showing a portion of a display device according to an embodiment;

FIGS. 9A to 9C are cross-sectional views schematically showing a light-emitting diode of a display device according to an embodiment;

FIG. 10A is a plan view schematically showing a pore structure of a display device according to an embodiment;

FIG. 10B is a perspective view schematically showing a pore structure of a display device according to an embodiment;

FIG. 11A is a cross-sectional view schematically showing a light-emitting diode of a display device according to another embodiment;

FIG. 11B is a cross-sectional view schematically showing a light-emitting diode of a display device according to another embodiment; and

FIG. 12 is a cross-sectional view schematically showing a portion of a display device according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure is subject to various modifications and may have many embodiments, certain of which are illustrated in the drawings and further described in the detailed description. The effects and features of the disclosure, and methods of achieving them will become clear with reference to the embodiments described below in detail together with the drawings. However, the disclosure is not limited to the embodiments described herein and may be implemented in various forms.

Hereinafter, embodiments will be described in detail with reference to the accompanying drawings, and when being described with reference to the drawings, the same or corresponding components are given the same reference numerals, and duplicate descriptions thereof will be omitted.

In the following embodiments, the terms “first”, “second”, etc. are not intended to be limiting, however are used to distinguish one component from another.

In the following embodiments, the singular expression includes the plural unless the context clearly indicates otherwise.

In the following embodiments, the terms including or that has, etc. are intended to imply the presence of the recited features or components and do not preclude the possibility of the addition of one or more other features or components.

In the following embodiments, when a portion of a film, area, component, etc. is the to be over or on top of another portion, this includes not only when it is directly on top of the other portion, but also when there are other films, areas, components, etc. arranged therebetween.

In the drawings, components may be exaggerated or reduced in size for ease of illustration. For example, the size and thickness of each configuration shown in the drawings are arbitrary for purposes of illustration and the disclosure is not necessarily limited to those shown.

In some embodiments, a particular sequence of processes may be performed in a different order than that described. For example, two processes described in succession may be performed substantially simultaneously, or may be performed in the opposite order from the order described.

In the specification, the expression such as “A and/or B” may include A, B, or A and B. Furthermore, the expression such as “at least one of A and B” may include A, B, or A and B.

In the following embodiments, when layers, regions, or components are connected to each other, the layers, the regions, or the components may be directly connected to each other, or another layer, another region, or another component may be interposed between the layers, the regions, or the components and thus the layers, the regions, or the components may be indirectly connected to each other. For example, in the following embodiments, when layers, regions, or components are electrically connected to each other, the layers, the regions, or the components may be directly electrically connected to each other, or another layer, another region, or another component may be interposed between the layers, the regions, or the components and thus the layers, the regions, or the components may be indirectly electrically connected to each other.

In the following embodiments, the terms x-axis, y-axis, and z-axis are not limited to, however may be interpreted in a broad sense to include three axes in a Cartesian coordinate system. For example, the x-axis, y-axis, and z-axis may be orthogonal to each other, however, may also refer to different directions that are not orthogonal to each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +10%, 5% or 3% of the stated value.

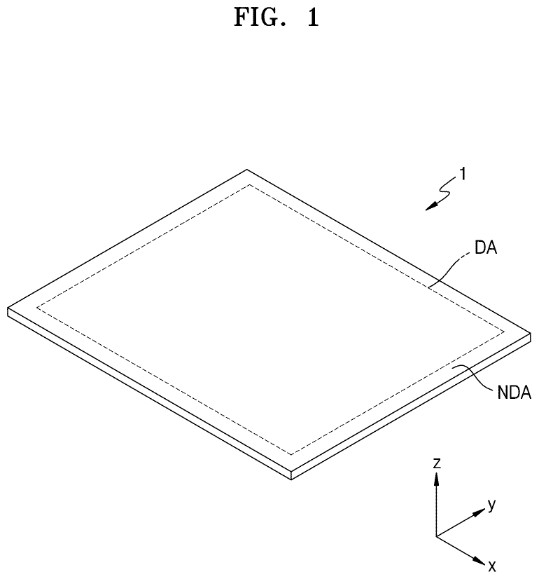

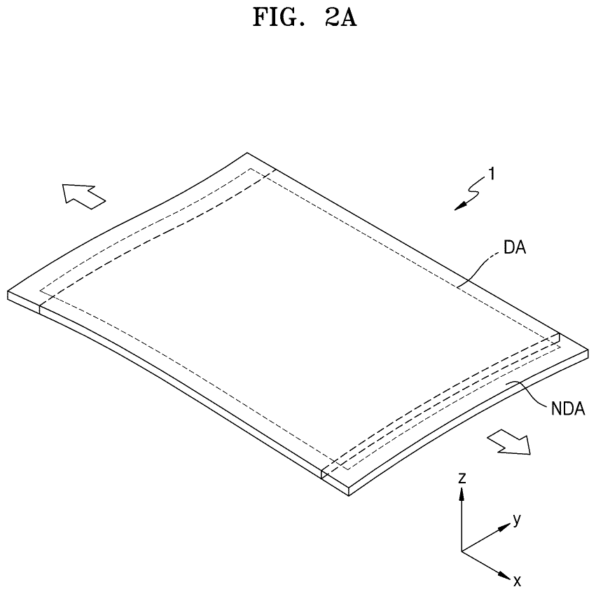

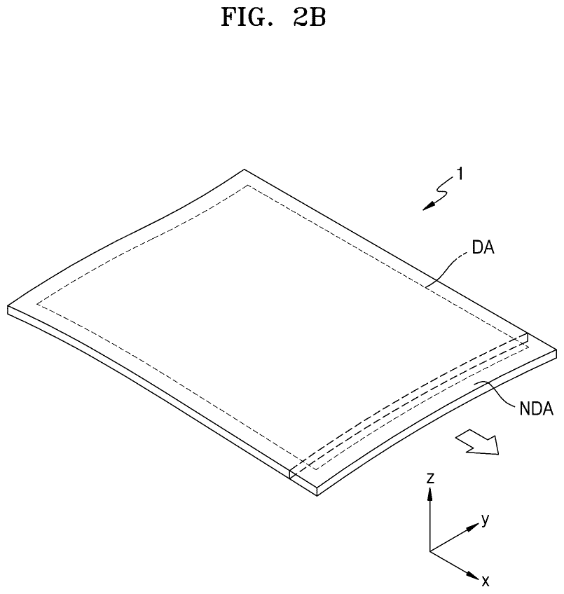

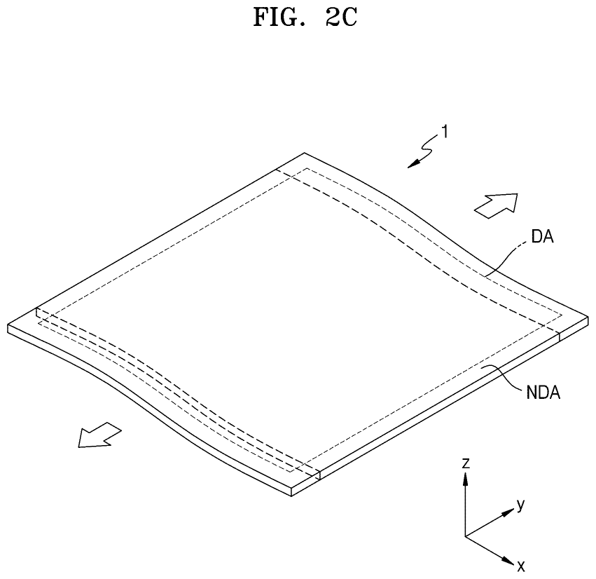

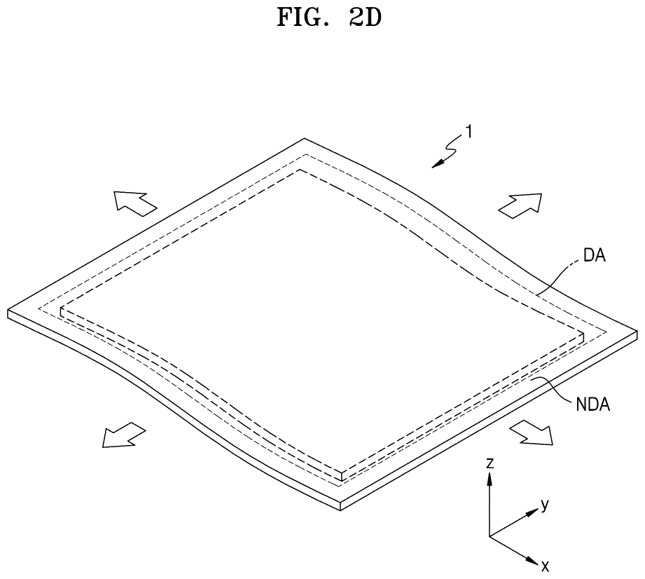

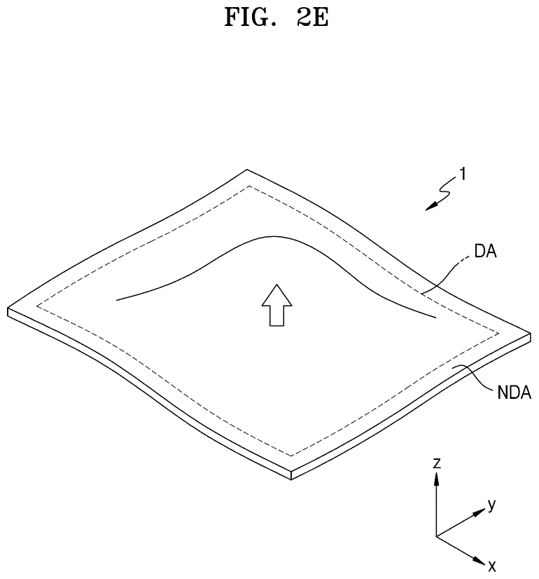

FIG. 1 is a perspective view schematically showing a display device 1 according to an embodiment. FIGS. 2A and 2B are perspective views showing the display device 1 of FIG. 1 stretched in a first direction. FIG. 2C is a perspective view showing the display device 1 of FIG. 1 stretched in a second direction. FIG. 2D is a perspective view showing the display device of FIG. 1 stretched in the first and second directions. FIG. 2E is a perspective view showing the display device 1 of FIG. 1 stretched in a third direction.

Referring to FIG. 1, the display device 1 may include a display area DA and a non-display area NDA. The display area DA may include a plurality of pixels. The display device 1 may provide a certain image by using light emitted from the plurality of pixels. The non-display area NDA may be placed outside the display area DA. The non-display area NDA may surround the entirety of the display area DA.

The display device 1 may be a stretchable display device and may be stretched or shrunk in various directions. The display device 1 may be stretched in a first direction (e.g., x direction and/or −x direction) by an external force applied by an external object or a user. In an embodiment, as shown in FIGS. 2A and 2B, the display area DA and/or the non-display area NDA of the display device 1 may be stretched in the first direction (e.g., x direction and/or −x direction). For example, as shown in FIG. 2A, the display area DA and/or the non-display area NDA of the display device 1 may be stretched in the x direction and −x direction. Alternatively, as shown in FIG. 2B, the display area DA and/or the non-display area NDA of the display device 1 may be stretched in the x direction while one side of the display device 1 is fixed.

The display device 1 may be stretched in the second direction (e.g., y direction and/or −y direction) by an external force applied by an external object or a user. In an embodiment, as shown in FIG. 2C, the display area DA and/or the non-display area NDA of the display device 1 may be stretched in the y direction and −y direction. In another embodiment, the display area DA and/or the non-display area NDA of the display device 1 may be stretched in the y direction or −y direction while one side of the display device 1 is fixed.

The display device 1 may be stretched in a plurality of directions, for example, in the first direction (e.g., x direction and/or −x direction) and the second direction (e.g., y direction and/or −y direction), by an external force applied by an external object or a part of a person's body. As shown in FIG. 2D, the display area DA and/or the non-display area NDA of the display device 1 may be stretched in the +x direction and the ty direction.

The display device 1 may be stretched in a third direction (e.g., z direction or −z direction) by an external force applied by an external object or a part of a person's body. In an embodiment, FIG. 2E shows that a portion of the display device 1, for example, a portion of the display area DA protrudes in the z direction. In another embodiment, a portion of the display device 1, for example, a portion of the display area DA may protrude in the z direction (or be dented in the −z direction).

Although FIGS. 2A to 2E show that the display device 1 is stretched in the first direction, the second direction, and/or the third direction, the disclosure is not limited thereto. In another embodiment, the display device 1 may be deformed into various irregular shapes, such as being bent or twisted along two or more axes.

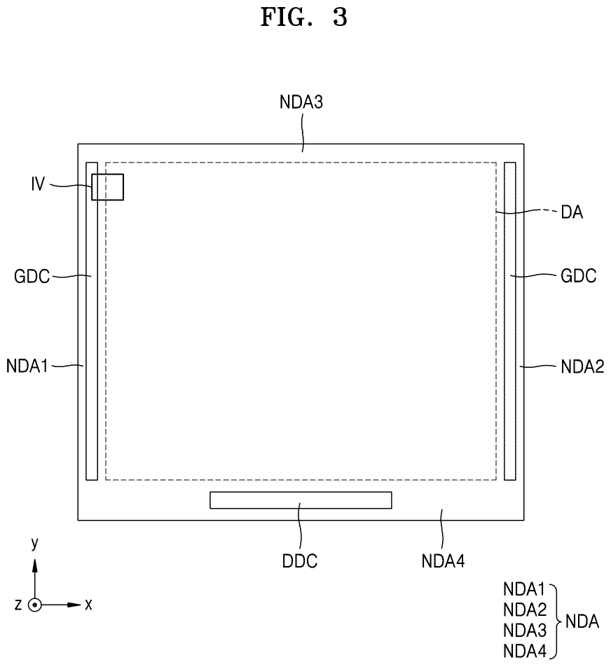

FIG. 3 is a plan view schematically showing a display device 1 according to an embodiment. As used herein, the “plan view” is a view in the third direction (z direction).

A plurality of pixels may be arranged in a display area DA of the display device 1. Each pixel may include sub-pixels that emit light of different colors. A light-emitting element corresponding to each sub-pixel may be arranged in the display area DA. A circuit for providing electrical signals to light-emitting elements arranged in the display area DA and transistors electrically connected to the light-emitting elements may be located in a non-display area NDA surrounding the display area DA. A gate driving circuit GDC may be arranged in each of a first non-display area NDA1 and a second non-display area NDA2 on opposite sides of the display area DA. The gate driving circuit GDC may include drivers for providing electrical signals to gate electrodes of the transistors electrically connected to the light-emitting elements. Although FIG. 3 shows that the gate driving circuit GDC is arranged in each of the first non-display area NDA1 and the second non-display area NDA2, the disclosure is not limited thereto. In another embodiment, the gate driving circuit GDC may be arranged in either the first non-display area NDA1 or the second non-display area NDA2.

A data driving circuit DDC may be arranged in a third non-display area NDA3 and/or a fourth non-display area NDA4, which connect the first non-display area NDA1 and the second non-display area NDA2 to each other. In an embodiment, FIG. 3 shows that the data driving circuit DDC is arranged in the fourth non-display area NDA4. In another embodiment, the data driving circuit DDC may be arranged in each of the third non-display area NDA3 and the fourth non-display area NDA4.

Although FIG. 3 shows that the data driving circuit DDC is arranged in the fourth non-display area NDA4 of the display device 1, the disclosure is not limited thereto. In another embodiment, the display device 1 may further include a flexible circuit board (not shown) electrically connected through a terminal portion (not shown) arranged in the fourth non-display area NDA4, and the data driving circuit DDC may be disposed on the flexible circuit board.

In some embodiments, the elongation rate of the non-display area NDA may be equal to or less than the elongation rate of the display area DA. In an embodiment, the elongation rate of the non-display area NDA may be different for each area. For example, the first non-display area NDA1, the second non-display area NDA2, and the third non-display area NDA3 may have substantially the same elongation rate, but the elongation rate of the fourth non-display area NDA4 may be less than the elongation rate of each of the first non-display area NDA1, the second non-display area NDA2, and the third non-display area NDA3.

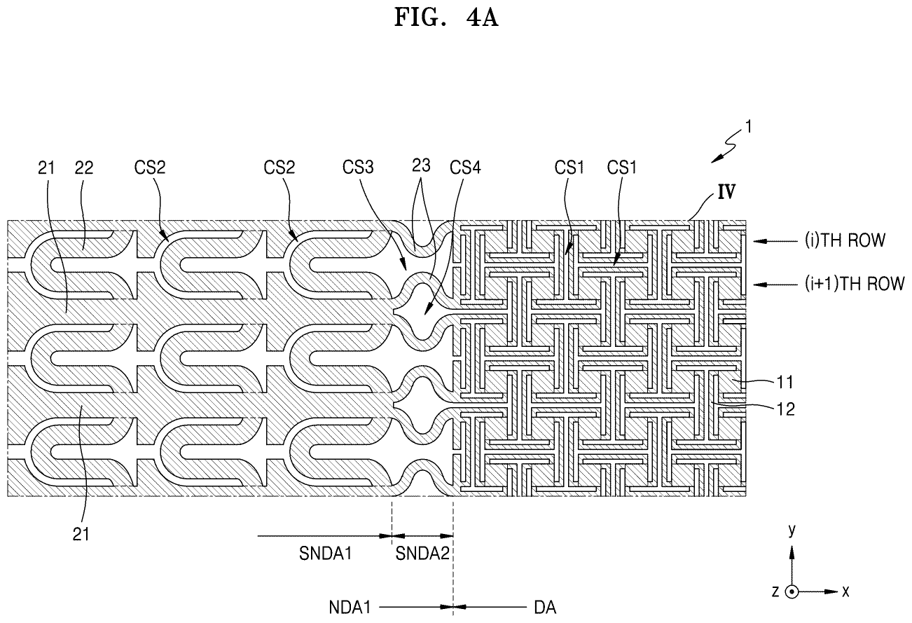

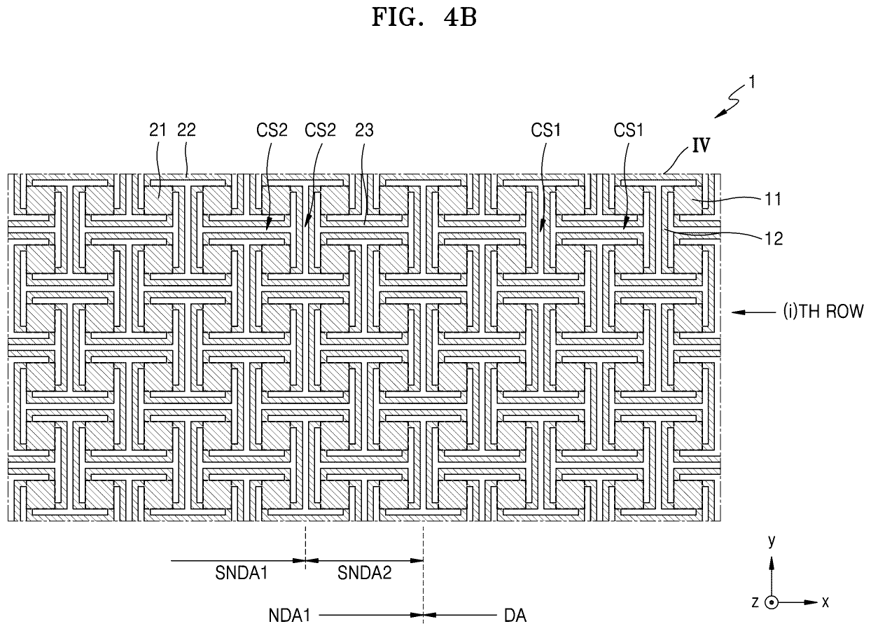

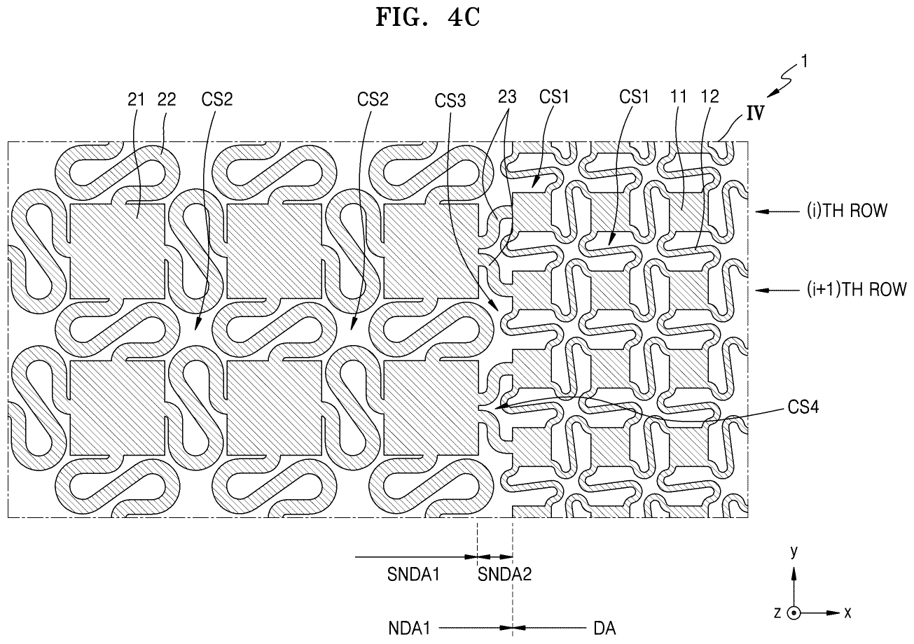

FIG. 4A is an enlarged plan view of an area IV of FIG. 3 as part of a display device 1 according to an embodiment.

Referring to FIG. 4A, the display device 1 is a stretchable display device, and may include first island portions 11 spaced apart from each other in a first direction (e.g., x direction or −x direction) and a second direction (e.g., y direction or −y direction) in the display area DA, and first bridge portions 12 connecting adjacent first island portions 11 to each other.

Each of the first island portions 11 may be connected to a plurality of first bridge portions 12. For example, each of the first island portions 11 may be connected to four first bridge portions 12. Two first bridge portions 12 may be disposed on opposite sides of the first island portion 11 in the first direction (e.g., x direction or −x direction), and the remaining two first bridge portions 12 may be disposed on opposite sides of the first island portion 11 in the second direction (e.g., y direction or −y direction). In an embodiment, the four first bridge portions 12 may be connected to the four sides of the first island portion 11, respectively. Each of the four first bridge portions 12 may be adjacent to each corner of the first island portion 11.

The first bridge portions 12 may be spaced apart from each other by a first opening CS1 located between the first bridge portions 12. In an embodiment, a first opening CS1 having approximately H shape and a first opening CS1 having approximately I shape obtained by rotating the H shape by 90 degrees may be alternately and repeatedly arranged in the first direction (e.g., x direction or −x direction) and the second direction (e.g., y direction or −y direction). Both ends of each first bridge portion 12 may be connected to each of the adjacent first island portions 11, and one side of each first bridge portion 12 may be spaced apart from one side of an adjacent first island portion 11 and/or one side of another first bridge portion 12 by the first opening CS1.

The display device 1 may include second island portions 21 spaced apart from each other in a non-display area, for example, the first non-display area NDA1 shown in FIG. 4A, and second bridge portions 22 connecting adjacent second island portions 21 to each other.

Each of the second island portions 21 may extend in the first direction (e.g., x direction or −x direction). The second island portions 21 may be spaced apart from each other in the second direction (e.g., y direction or −y direction) that crosses the first direction (e.g., x direction or −x direction). Each second island portion 21 may include drivers of the gate driving circuit GDC (see FIG. 2) described with reference to FIG. 3.

The second bridge portion 22 may have a serpentine shape. The length of the second bridge portion 22 may be greater than the shortest distance between adjacent second island portions 21 in the second direction (e.g., y direction or −y direction). In an embodiment, the second bridge portion 22 may have an approximately omega (0) shape that is convex toward the first direction (e.g., x direction or −x direction). The second bridge portions 22 may be arranged between adjacent second island portions 21 and may be spaced apart from each other.

The second bridge portions 22 between adjacent second island portions 21 may be spaced apart from each other by second openings CS2. Between the adjacent second island portions 21, the second openings CS2 and the second bridge portions 22 may be alternately arranged in the first direction (e.g., x direction or −x direction). The second openings CS2 may have the same shape. Both ends of each second bridge portion 22 may be connected to each of the adjacent second island portions 21, and one side of each second bridge portion 22 may be spaced apart from one side of an adjacent second island portion 21 and/or one side of another second bridge portion 22 by the second opening CS2.

One of the second island portions 21 arranged in the first non-display area NDA1 may correspond to a plurality of rows of first island portions 11 arranged in the display area DA1. For example, one of the second island portions 21 arranged in the first non-display area NDA1 may correspond to first island portions 11 arranged in the (i)th row and first island portions 11 arranged in the (i+1)th row in the display area DA (where I is a positive number greater than 0). Although FIG. 4A shows that one second island portion 21 corresponds to two rows of first island portions 11, but the disclosure is not limited thereto. In another embodiment, one second island portion 21 arranged in the first non-display area NDA1 may correspond to n rows of first island portions 11 arranged in the display area DA1 (where n is a positive number that is equal to or greater than 3).

The non-display area, for example, the first non-display area NDA1, may include a first sub-non-display area SNDA1 in which the second island portions 21 and the second bridge portions 22, described above, are arranged, and a second sub-non-display area SNDA2 between the first sub-non-display area SNDA1 and the display area DA. Third bridge portions 23 may be arranged in the second sub-non-display area SNDA2 to connect the display area DA with the first sub-non-display area SNDA1. One end of the third bridge portion 23 may be connected to the second island portion 21 and/or the second bridge portion 22, and the other end of the third bridge portion 23 may be connected to the first island portion 11 and/or the first bridge portion 12.

The third bridge portion 23 may have a serpentine shape. In an embodiment, the shape of the third bridge portion 23 may be different from the shape of each of the first bridge portion 12 and the second bridge portion 22. In an embodiment, as shown in FIG. 4A, the third bridge portion 23 may have an approximately Q shape that is convex toward the second direction (e.g., y direction or −y direction). The third bridge portions 23 may have a symmetrical structure, in which one of the adjacent third bridge portions 23 arranged in the second direction (e.g., y direction or −y direction) is convex in the y direction and the other is convex in the −y direction. Between the third bridge portions 23, third openings CS3 and fourth openings CS4 of different shapes may have a repeated structure. The width of the third bridge portion 23 may be different from the width of the first bridge portion 12 and the width of the second bridge portion 22. In an embodiment, the width of the third bridge portion 23 may be greater than the width of the first bridge portion 12 and may be less than the width of the second bridge portion 22.

FIG. 4A shows that the second island portion 21 and the second bridge portion 22 in the non-display area, for example, the first non-display area NDA1, have different shapes from the first island portion 11 and the first bridge portion 12, respectively, in the display area DA. In another embodiment of the disclosure, the second island portion 21 and the second bridge portion 22 in the non-display area may have the same shape as the first island portion 11 and the first bridge portion 12, respectively, in the display area DA.

FIG. 4B is an enlarged plan view of an area IV of FIG. 3 as part of a display device 1 according to an embodiment.

Referring to FIG. 4B, the display device 1 is a stretchable display device, and may include first island portions 11 spaced apart from each other in a display area DA and first bridge portions 12 spaced apart from each other by a first opening CS1 and connecting adjacent first island portions 11 to each other. The structure of the display area DA in FIG. 4B may be the same as the structure of the display area DA previously described with reference to FIG. 4A.

The display device 1 may include second island portions 21 and second bridge portions 22, arranged in a non-display area, for example, a first non-display area NDA1. In an embodiment, the second island portions 21 and the second bridge portions 22 may have substantially the same shape as the first island portions 11 and the first bridge portions 12, respectively.

The second island portions 21 may be spaced apart from each other in a first direction (e.g., x direction or −x direction) and a second direction (e.g., y direction or −y direction) in the non-display area, for example, the first non-display area NDA1. Each of the second bridge portions 22 may connect adjacent second island portions 21 to each other. The second bridge portions 22 may be spaced apart from each other by a second opening CS2 located between the second bridge portions 22.

The second opening CS2 may have substantially the same shape as the first opening CS1. For example, a second opening CS2 having approximately H shape and a second opening CS2 having approximately I shape may be alternately and repeatedly arranged in the non-display area, for example, the first non-display area NDA1. Both ends of each second bridge portion 22 may be connected to each of the adjacent second island portions 21, and one side of each second bridge portion 22 may be spaced apart from one side of an adjacent second island portion 21 and/or one side of another second bridge portion 22 by the second opening CS2.

Each second island portion 21 may be connected to four second bridge portions 22. Each second island portion 21 may include drivers of the gate driving circuit GDC (see FIG. 2) described with reference to FIG. 3.

Second island portions 21 in one row arranged in the first non-display area NDA1 may correspond to first island portions 11 in one row arranged in the display area DA1. For example, second island portions 21 arranged in the (i)th row in the first direction (e.g., x direction or −x direction) in the first non-display area NDA1 may correspond to first island portions 11 arranged in the same row, for example, the (i)th row, in the display area DA (where i is a positive number greater than 0).

The display device 1 may include third bridge portions 23 arranged in the second sub-non-display area SNDA2 for connecting the display area DA to the first sub-non-display area SNDA1. A non-display area, for example, the first non-display area NDA1, may include a first sub-non-display area SNDA1 in which the second island portions 21 and the second bridge portions 22 are arranged, and a second sub-non-display area SNDA2 including third bridge portions 23 and located between the first sub-non-display area SNDA1 and the display area DA. The third bridge portion 23 may be substantially the same as the first bridge portion 12 and the second bridge portion 22. For example, the width of the third bridge portion 23 may be the same as the width of the first bridge portion 12 and the width of the second bridge portion 22.

FIG. 4C is an enlarged plan view of an area IV of FIG. 3 as part of a display device according to an embodiment.

Referring to FIG. 4C, the display device 1 is a stretchable display device, and may include first island portions 11 spaced apart from each other in a first direction (e.g., x direction or −x direction) and a second direction (e.g., y direction or −y direction) in the display area DA, and first bridge portions 12 connecting adjacent first island portions 11 to each other.

The first bridge portions 12 may be arranged to be spaced apart from each other by the first opening CS1 located between the first bridge portions 12. The first bridge portion 12 may have a serpentine shape. For example, as shown in FIG. 4C, the first bridge portion 12 may have the shape of approximately ‘alphabet S’.

Each of the first island portions 11 may be connected to a plurality of first bridge portions 12. For example, each of the first island portions 11 may be connected to four first bridge portions 12. Two first bridge portions 12 may be disposed on opposite sides of the first island portion 11 in the first direction (e.g., x direction or −x direction), and the remaining two first bridge portions 12 may be disposed on opposite sides of the first island portion 11 in the second direction (e.g., y direction or −y direction). The four first bridge portions 12 may be connected to the four sides of the first island portion 11, respectively. Each of the four first bridge portions 12 may be adjacent to each corner of the first island portion 11.

The display device 1 may include second island portions 21 spaced apart from each other in a first direction (e.g., x direction or −x direction) and a second direction (e.g., y direction or −y direction) in a non-display area, for example, in the first non-display area NDA1 shown in FIG. 4C, and second bridge portions 22 connecting adjacent second island portions 21 to each other.

The second bridge portions 22 may be arranged to be spaced apart from each other by the second opening CS2 located between the second bridge portions 22. The second bridge portion 22 may have a serpentine shape. For example, as shown in FIG. 4C, the second bridge portion 22 may have the shape of approximately ‘alphabet S’. The size and/or width of the second bridge portion 22 may be different from the size and/or width of the first bridge portion 12. For example, the size and/or width of the second bridge portion 22 may be greater than the size and/or width of the first bridge portion 12. The radius of curvature of a round portion of the second bridge portion 22 may be different from the radius of curvature of a round portion of the first bridge portion 12. For example, the radius of curvature of the round portion of the second bridge portion 22 may be greater than the radius of curvature of the round portion of the first bridge portion 12.

Each of the second island portions 21 may be connected to a plurality of second bridge portions 22. Each of the second island portions 21 may be connected to four second bridge portions 22. Two second bridge portions 22 may be disposed on opposite sides of the second island portion 21 in the first direction (e.g., x direction or −x direction), and the remaining two second bridge portions 22 may be disposed on opposite sides of the second island portion 21 in the second direction (e.g., y direction or −y direction). In an embodiment, the four second bridge portions 22 may be connected to the four sides of the second island portion 21, respectively. Each second bridge portion 22 may be connected to a central portion of each side of the second island portion 21.

Second island portions 21 in one row arranged in the first non-display area NDA1 may correspond to first island portions 11 in a plurality of rows arranged in the display area DA1. For example, the second island portions 21 in one row arranged in the first non-display area NDA1 may correspond to first island portions 11 arranged in the (i)th row of the display area DA and first island portions 11 arranged in the (i+1)th row (where i is a positive number greater than 0). In another embodiment, one row of second island portions 21 may correspond to n rows of first island portions 11 (where n is a positive number that is equal to or greater than 3).

The non-display area, for example, the first non-display area NDA1, may include a first sub-non-display area SNDA1 in which the second island portions 21 and the second bridge portions 22, described above, are arranged, and a second sub-non-display area SNDA2 between the first sub-non-display area SNDA1 and the display area DA. Third bridge portions 23 may be arranged in the second sub-non-display area SNDA2 to connect the display area DA with the first sub-non-display area SNDA1. One end of the third bridge portion 23 may be connected to the second island portion 21 and the other end of the third bridge portion 23 may be connected to the first island portion 11. For example, one end of the third bridge portion 23 may be connected to a central portion of one side of the second island portion 21, and the other end of the third bridge portion 23 may be connected to a central portion of one side of the first island portion 11.

The third bridge portion 23 may have a serpentine shape. In an embodiment, the shape of the third bridge portion 23 may be different from the shape of each of the first bridge portion 12 and the second bridge portion 22. The width of the third bridge portion 23 may be different from the width of the first bridge portion 12 and the width of the second bridge portion 22. The width of the third bridge portion 23 may be greater than the width of the first bridge portion 12 and may be less than the width of the second bridge portion 22. Third openings CS3 and fourth openings CS4 of different shapes may be alternately arranged between the third bridge portions 23 in the second direction (e.g., y direction or −y direction).

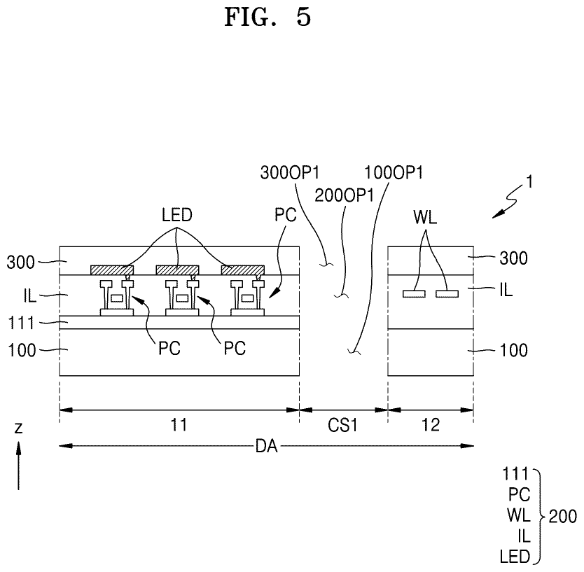

FIG. 5 is a cross-sectional view schematically showing a first island portion 11 and a first bridge portion 12 disposed in a display area DA of a stretchable display device 1 according to an embodiment.

Referring to FIG. 5, the first island portion 11 and the first bridge portion 12 disposed in the display area DA may be spaced apart from each other with a first opening CS1 therebetween. The first island portion 11 may include light-emitting elements LED and a circuit (e.g., pixel driving circuit portion (“PC”) for driving the light-emitting elements LED electrically connected thereto, and the first bridge portion 12 may include a wiring line WL electrically connected to pixel driving circuit portions PC arranged in each of the adjacent first island portions 11.

In the first island portion 11, a buffer layer 111 including an inorganic insulating material may be disposed on a substrate 100, and a pixel driving circuit portion PC may be disposed on the buffer layer 111. An insulating layer IL including an inorganic insulating material and/or an organic insulating material may be disposed between the pixel driving circuit portion PC and the light-emitting element LED. The light-emitting element LED may be disposed on the insulating layer IL and may be electrically connected to a corresponding pixel driving circuit portion PC. Light-emitting elements LED may emit light of different colors or the same color. In an embodiment, each of the light-emitting elements LED may emit red light, green light, or blue light. In some embodiments, the light-emitting elements LED may emit white light. In another embodiment, each of the light-emitting elements LED may emit red light, green light, blue light, or white light.

The substrate 100 may include a polymer resin, such as polyethersulfone, polyarylate, polyether imide, polyethylene naphthalate, polyethylene terephthalate, polyphenylene sulfide, polyimide, polycarbonate, cellulose triacetate, or cellulose acetate propionate. In an embodiment, the substrate 100 may include a single layer including the aforementioned resin. In another embodiment, the substrate 100 may have a multi-layered structure including a base layer including the aforementioned polymer resin and a barrier layer including an inorganic insulating material. The substrate 100 including a polymer resin may be flexible, rollable, or bendable.

In an embodiment, FIG. 5 shows that three pixel driving circuit portions PC are arranged in each of the first island portions 11 and three light-emitting elements LED are connected to each of the pixel driving circuit portions PC. However, the disclosure is not limited thereto. In another embodiment, the number of pixel driving circuit portions PC and light-emitting elements LED arranged in the first island portion 11 may be one, two, or four or more.

An encapsulation layer 300 may be disposed on the light-emitting elements LED and may protect the light-emitting elements LED from external force and/or moisture penetration. The encapsulation layer 300 may include an inorganic encapsulation layer and/or an organic encapsulation layer. In some embodiments, the encapsulation layer 300 may have a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material, such as resin. In some embodiments, the encapsulation layer 300 may include urethane epoxy acrylate. The encapsulation layer 300 may include a photosensitive material, such as photoresist.

In the first bridge portion 12, an insulating layer IL including an organic insulating material may be disposed on the substrate 100. When the stretchable display device 1 is stretched, unlike the first island portion 11, there may not be a layer including an inorganic insulating material, which is prone to cracks, in the first bridge portion 12, which is relatively deformed.

In an embodiment, the substrate 100 corresponding to the first bridge portion 12 may have the same stacked structure as the substrate 100 corresponding to the first island portion 11. In an embodiment, the substrate 100 corresponding to the first bridge portion 12 and the substrate 100 corresponding to the first island portion 11 may be polymer resin layers formed together in the same process. In another embodiment, the substrate 100 corresponding to the first bridge portion 12 may have a different stack structure from the substrate 100 corresponding to the first island portion 11. In some embodiments, the substrate 100 corresponding to the first island portion 11 may have a multi-layered structure including a base layer including a polymer resin and a barrier layer including an inorganic insulating material, and the substrate 100 corresponding to the first bridge portion 12 may have a structure of a polymer resin layer without a layer including an inorganic insulating material.

As described above, wiring lines WL of the first bridge portion 12 may be signal lines (e.g., gate lines and data lines) for providing electrical signals to transistors included in the pixel driving circuit portion PC of the first island portion 11, or voltage lines (e.g., driving voltage lines and initialization voltage lines) for providing voltages. The encapsulation layer 300 may also be arranged in the first bridge portion 12. In another embodiment, the encapsulation layer 300 may not be present in the first bridge portion 12.

Referring to FIGS. 4A to 4C and FIG. 5, the substrate 100 corresponding to the first island portion 11 and the substrate 100 corresponding to the first bridge portion 12 may be connected to each other. In other words, the plan views shown in FIGS. 4A to 4C may be substantially the same as the plan view of the substrate 100 in FIG. 5. In other words, the substrate 100 may include an area corresponding to the first island portion 11, an area corresponding to the first bridge portion 12, and an opening 100OP1 having the same shape as the first opening CS1.

Similarly, the encapsulation layer 300 corresponding to the first island portion 11 and the encapsulation layer 300 corresponding to the first bridge portion 12 may be connected to each other. For example, the plan views shown in FIGS. 4A to 4C may be substantially the same as the plan view of the encapsulation layer 300. In other words, the encapsulation layer 300 may include an area corresponding to the first island portion 11, an area corresponding to the first bridge portion 12, and an opening 300OP1 having the same shape as the first opening CS1.

A circuit-light-emitting element layer 200 between the substrate 100 and the encapsulation layer 300 may include a buffer layer 111, a pixel driving circuit portion PC, a wiring line WL, an insulating layer IL, and a light-emitting element LED. Similar to the substrate 100, the plan view shown in FIGS. 4A to 4C may be substantially the same as the plan view of the circuit-light-emitting element layer 200. In other words, the circuit-light-emitting element layer 200 may define an opening 200OP1 therein having the same shape as the first opening CS1.

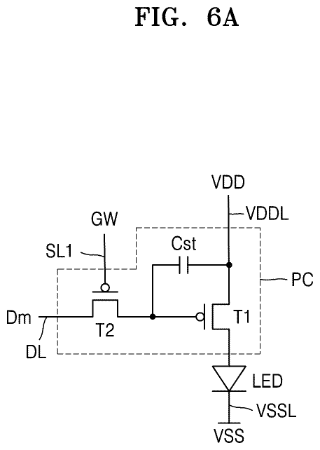

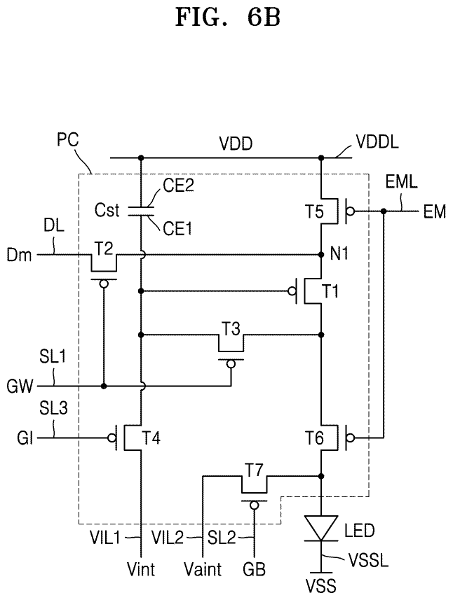

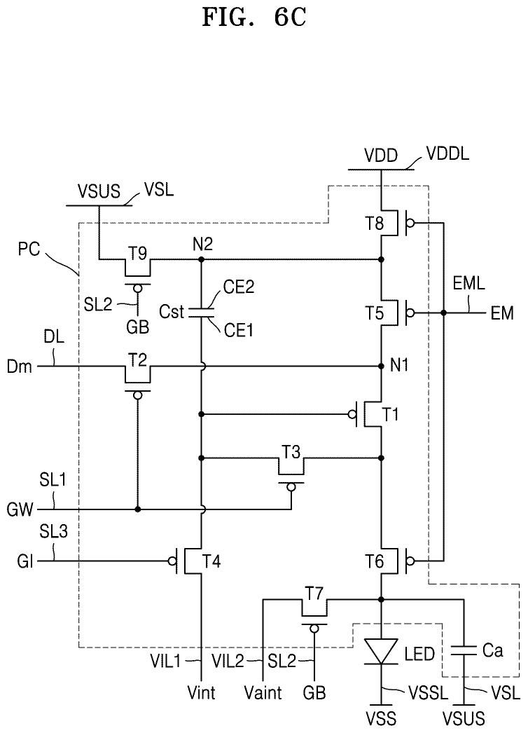

FIGS. 6A to 6C are equivalent circuit diagrams of a sub-pixel of the stretchable display device 1 according to an embodiment.

Referring to FIG. 6A, a light-emitting element LED corresponding to the sub-pixel may be electrically connected to a pixel driving circuit PC, and the pixel driving circuit PC may include a first transistor T1, a second transistor T2, and a storage capacitor Cst. The pixel driving circuit PC may be electrically connected to a signal line and a voltage line. The signal line may include a gate line such as a first scan line SL1, and a data line DL, and the voltage line may include a first voltage line VDDL.

The second transistor T2 may be electrically connected to the first scan line SL1 and the data line DL. The first scan line SL1 may provide a first scan signal GW1 to a gate electrode of the second transistor T2. The second transistor T2 may be configured to transmit a data signal Dm input from the data line DL to the first transistor T1 according to the first scan signal GW1 input from the first scan line SL1.

The storage capacitor Cst may be electrically connected to the second transistor T2 and the first voltage line VDDL and may store a voltage corresponding to the difference between a voltage received from the second transistor T2 and a first power voltage VDD supplied by the first voltage line VDDL.

The first transistor T1 may be a driving transistor and may be configured to control a driving current flowing through the light-emitting element LED. The first transistor T1 may be connected to the first voltage line VDDL and the storage capacitor Cst. The first transistor T1 may be configured to control a driving current flowing from the first voltage line VDDL to the light-emitting element LED in response to a voltage value stored in the storage capacitor Cst. The light-emitting element LED may emit light having a certain brightness by the driving current. A first electrode of the light-emitting element LED may be electrically connected to the first transistor T1, and a second electrode of the light-emitting element LED may be electrically connected to a second voltage line VSSL that supplies a second power voltage VSS, which may be referred to as “low-potential voltage”.

FIG. 6A shows that the pixel driving circuit PC includes two transistors and one storage capacitor. However, in another embodiment, the pixel driving circuit PC may include three or more transistors.

Referring to FIG. 6B, a pixel driving circuit portion PC may include a first transistor T1, a second transistor T2, a third transistor T3, a fourth transistor T4, a fifth transistor T5, a sixth transistor T6, a seventh transistor T7, and a storage capacitor Cst.

The pixel driving circuit PC is electrically connected to signal lines and voltage lines. The signal lines may include gate lines, such as a first scan line SL1, a second scan line SL2, a third scan line SL3, a fourth scan line SL4, and an emission control line EML, and a data line DL. The voltage lines may include first and second initialization voltage lines VIL1 and VIL2 and a first voltage line VDDL.

The first voltage line VDDL may transmit a first power voltage VDD to the first transistor T1. The first initialization voltage line VIL1 may transmit a first initialization voltage Vint, which initializes the first transistor T1, to the pixel driving circuit PC. The second initialization voltage line VIL2 may transmit a second initialization voltage Vaint, which initializes a first electrode of a light-emitting element LED, to the pixel driving circuit PC.

The first transistor T1 may be electrically connected to the first voltage line VDDL via the fifth transistor T5 and may be electrically connected to the light-emitting element LED via the sixth transistor T6. The first transistor T1 may function as a driving transistor and may be configured to receive a data signal Dm according to a switching operation of the second transistor T2 and supply a driving current to the light-emitting element LED.

The second transistor T2 may be a data writing transistor and may be electrically connected to the first scan line SL1 and the data line DL. The second transistor T2 may be electrically connected to the first voltage line VDDL via the fifth transistor T5. The second transistor T2 may be configured to be turned on according to a first scan signal GW received through the first scan line SL1 and transmit the data signal Dm transmitted to the data line DL to a first node N1. That is, the second transistor T2 may be configured to perform a switching operation.

The third transistor T3 may be electrically connected to the first scan line SL1 and to the light-emitting element LED via the sixth transistor T6. The third transistor T3 may be configured to be turned on according to a first scan signal GW received through the first scan line SL1 and diode-connect the first transistor T1.

The fourth transistor T4 may be a first initialization transistor and may be electrically connected to the third scan line SL3 and the first initialization voltage line VIL1. The fourth transistor T4 may be configured to be turned on according to a third scan signal GI received through the third scan line SL3 and transmit the first initialization voltage Vint from the first initialization voltage line VIL1 to a gate electrode of the first transistor T1 to initialize the voltage of the gate electrode of the first transistor T1. The third scan signal GI may correspond to the first scan signal of another pixel driving circuit portion arranged in the previous row of a corresponding pixel driving circuit portion PC.

The fifth transistor T5 may be an operation control transistor, and the sixth transistor T6 may be an emission control transistor. The fifth transistor T5 and the sixth transistor T6 may be electrically connected to the emission control line EML and may be configured to be simultaneously turned on according to an emission control signal EM received through the emission control line EML and form a current path so that a driving current may flow from the first voltage line VDDL to the light-emitting element LED.

The seventh transistor T7 may be a second initialization transistor and may be electrically connected to the second scan line SL2, the second initialization voltage line VIL2, and the sixth transistor T6. The seventh transistor T7 may be configured to be turned on according to a second scan signal GB received through the second scan line SL2 and transmit the second initialization voltage Vaint from the second initialization voltage line VIL2 to the first electrode of the light-emitting element LED to initialize the first electrode of the light-emitting element LED.

The storage capacitor Cst may include a first electrode CE1 and a second electrode CE2. The first electrode CE1 may be electrically connected to the gate electrode of the first transistor T1, and the second electrode CE2 may be electrically connected to the first voltage line VDDL. The storage capacitor Cst may store and maintains a voltage corresponding to the voltage difference between the first voltage line VDDL and the gate electrode of the first transistor T1, thereby maintain the voltage applied to the gate electrode of the first transistor T1.

Referring to FIG. 6C, a pixel driving circuit portion PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel driving circuit PC may be electrically connected to signal lines and voltage lines. The signal lines may include gate lines, such as a first scan line SL1, a second scan line SL2, a third scan line SL3, a fourth scan line SL4, and an emission control line EML, and a data line DL. The voltage lines may include first and second initialization voltage lines VIL1 and VIL2, a maintenance voltage line VSL, and a first voltage line VDDL.

The first voltage line VDDL may transmit a first power voltage VDD to the first transistor T1. The first initialization voltage line VIL1 may transmit a first initialization voltage Vint, which initializes the first transistor T1, to the pixel driving circuit PC. The second initialization voltage line VIL2 may transmit a second initialization voltage Vaint, which initializes a first electrode of a light-emitting element LED, to the pixel driving circuit PC. The maintenance voltage line VSL may provide a maintenance voltage VSUS to a second node N2, for example, a second electrode CE2 of the storage capacitor Cst, during an initialization period and a data writing period.

The first transistor T1 may be electrically connected to the first voltage line VDDL via the fifth transistor T5 and the eighth transistor T8 and may be electrically connected to the light-emitting element LED via the sixth transistor T6. The first transistor T1 may function as a driving transistor and may be configured to receive a data signal Dm according to a switching operation of the second transistor T2 and supply a driving current to the light-emitting element LED.

The second transistor T2 may be electrically connected to the first scan line SL1 and the data line DL and may be electrically connected to the first voltage line VDDL via the fifth transistor T5 and the eighth transistor T8. The second transistor T2 may be configured to be turned on according to a first scan signal GW received through the first scan line SL1 and transmit the data signal Dm transmitted to the data line DL to a first node N1. That is, the second transistor T2 may be configured to perform a switching operation.

The third transistor T3 may be electrically connected to the first scan line SL1 and to the light-emitting element LED via the sixth transistor T6. The third transistor T3 may be configured to be turned on according to a first scan signal GW received through the first scan line SL1 and diode-connect the first transistor T1, thereby compensating for the threshold voltage of the first transistor T1.

The fourth transistor T4 may be electrically connected to the third scan line SL3 and the first initialization voltage line VIL1 and may be configured to be turned on according to a third scan signal GI received through the third scan line SL3 and transmit the first initialization voltage Vint from the first initialization voltage line VIL1 to a gate electrode of the first transistor T1 to initialize the voltage of the gate electrode of the first transistor T1. The third scan signal GI may correspond to the first scan signal of another pixel driving circuit portion arranged in the previous row of a corresponding pixel driving circuit portion PC.

The fifth transistor T5, the sixth transistor T6, and the eighth transistor T8 may be electrically connected to the emission control line EML and may be configured to be simultaneously turned on according to an emission control signal EM received through the emission control line EML and form a current path so that a driving current may flow from the first voltage line VDDL to the light-emitting element LED.

The seventh transistor T7 may be a second initialization transistor and may be electrically connected to the second scan line SL2, the second initialization voltage line VIL2, and the sixth transistor T6. The seventh transistor T7 may be configured to be turned on according to a second scan signal GB received through the second scan line SL2 and transmit the second initialization voltage Vaint from the second initialization voltage line VIL2 to the first electrode of the light-emitting element LED to initialize the first electrode of the light-emitting element LED.

The ninth transistor T9 may be electrically connected to the second scan line SL2, the second electrode CE2 of the storage capacitor Cst, and the maintenance voltage line VSL. The ninth transistor T9 may be configured to be turned on according to a second scan signal GB received through the second scan line SL2 and transmit a maintenance voltage VSUS to a second node N2, for example, the second electrode CE2 of the storage capacitor Cst, during an initialization period and a data writing period.

The eighth transistor T8 and the ninth transistor T9 may each be electrically connected to the second node N2, for example, the second electrode CE2 of the storage capacitor Cst. In some embodiments, in the initialization period and the data writing period, the eighth transistor T8 may be turned off and the ninth transistor T9 may be turned on, and in an emission period, the eighth transistor T8 may be turned on and the ninth transistor T9 may be turned off. Because the maintenance voltage VSUS is transmitted to the second node N2 in the initialization period and the data writing period, the uniformity (e.g., long range uniformity (“LRU”)) of luminance of the stretchable display device according to the voltage drop of the first voltage line VDDL may be effectively improved.

The storage capacitor Cst may include a first electrode CE1 and a second electrode CE2. The first electrode CE1 may be electrically connected to the gate electrode of the first transistor T1, and the second electrode CE2 may be electrically connected to the eighth transistor T8 and the ninth transistor T9.

The auxiliary capacitor Ca may be electrically connected to the sixth transistor T6, the maintenance voltage line VSL, and the first electrode of the light-emitting element LED. The auxiliary capacitor Ca may store and maintain a voltage corresponding to the voltage difference between the first electrode of the light-emitting element LED and the maintenance voltage line VSL while the seventh transistor T7 and the ninth transistor T9 are turned on, and thus may prevent black luminance from increasing when the sixth transistor T6 is turned off.

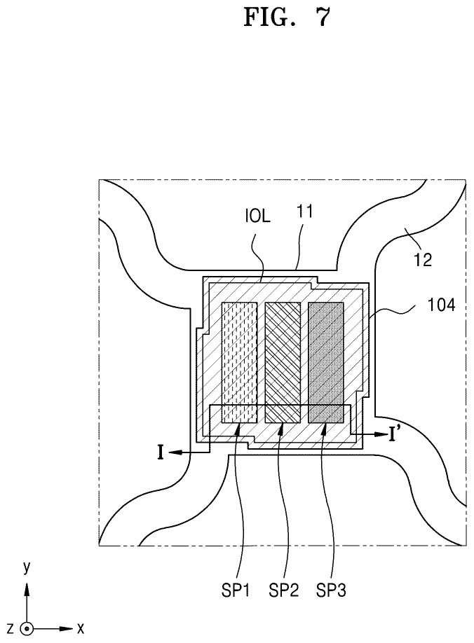

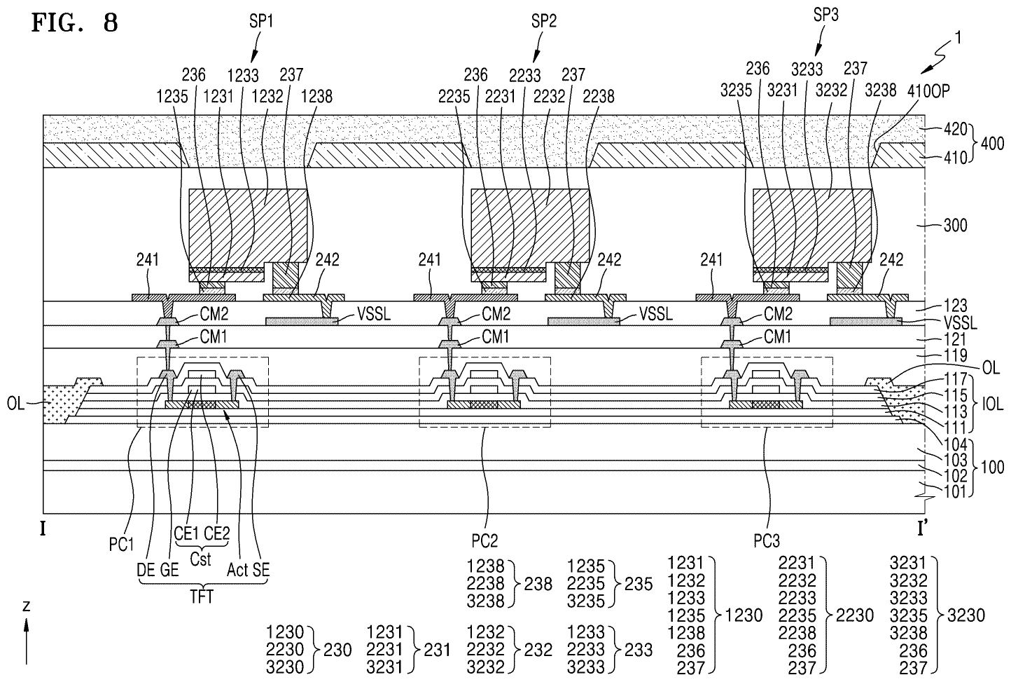

FIG. 7 is a plan view schematically showing a portion of a display device according to an embodiment. FIG. 8 is a cross-sectional view schematically showing a portion of a display device according to an embodiment.

Referring to FIG. 7, the display device 1 is a stretchable display device, and may include first island portions 11 spaced apart from each other in a first direction (e.g., x direction) and a second direction (e.g., y direction), and first bridge portions 12 connecting adjacent first island portions 11 to each other. The first bridge portion 12 may have a serpentine shape, for example, an approximately “S” shape. Although FIG. 7 shows that each of the first island portions 11 is quadrangular (e.g., square), but the disclosure is not limited thereto. The first island portion 11 may be rectangular, polygonal with five or more sides, or circular in another embodiment.

The first island portion 11 may be connected to a plurality of first bridge portions 12. For example, the first island portion 11 may be connected to four first bridge portions 12. Two first bridge portions 12 may be disposed on opposite sides of the first island portion 11 in the first direction (e.g., x direction), and the remaining two first bridge portions 12 may be disposed on opposite sides of the first island portion 11 in the second direction (e.g., y direction). The four first bridge portions 12 may be connected to the four sides of the first island portion 11, respectively. Each first bridge portion 12 may be disposed adjacent to a corner of the first island portion 11.

A plurality of sub-pixels may be arranged in the first island portion 11. The plurality of sub-pixels may include a first sub-pixel SP1, a second sub-pixel SP2, and a third sub-pixel SP3, and the first sub-pixel SP1, the second sub-pixel SP2, and the third sub-pixel SP3 may emit light of different colors. For example, the first sub-pixel SP1 may emit red light, the second sub-pixel SP2 may emit green light, and the third sub-pixel SP3 may emit blue light. Red light may be light belonging to a wavelength band of about 580 nanometers (nm) to about 780 nm, green light may be light belonging to a wavelength band of about 495 nm to about 580 nm, and blue light may be light belonging to a wavelength band of about 400 nm to about 495 nm.

Referring to FIGS. 7 and 8, each of the plurality of sub-pixels may include a light-emitting element LED (see FIG. 5), for example, a light-emitting diode. In an embodiment, the light-emitting diode may be an inorganic light-emitting diode. Accordingly, a first light-emitting diode 1230 that emits red light, a second light-emitting diode 2230 that emits green light, and a third light-emitting diode 3330 that emits blue light may be arranged in the first island portion 11.

First to third pixel driving circuit portions PC1, PC2, and PC3 may be disposed between a substrate 100 and the first to third light-emitting diodes 1230, 2230, and 3230. Each of the first to third pixel driving circuit portions PC1, PC2, and PC3 may include a transistor and a storage capacitor as previously described with reference to FIGS. 6A to 6C. In an embodiment, the first to third pixel driving circuit portions PC1, PC2, and PC3 are shown as having the same structure as the pixel driving circuit portion PC described with reference to FIG. 6A, and the specific structure is the same as described above.

Referring to FIG. 8, the substrate 100 corresponding to the first island portion 11 may include a first sub-substrate 101, a first barrier layer 102, a second sub-substrate 103, and a second barrier layer 104. The first sub-substrate 101 and the second sub-substrate 103 may each include a polymer resin, such as polyethersulfone, polyarylate, polyether imide, polyethylene naphthalate, polyethylene terephthalate, polyphenylene sulfide, polyimide, polycarbonate, cellulose triacetate, or cellulose acetate propionate. The first barrier layer 102 and the second barrier layer 104 may each include an inorganic insulating material, such as silicon oxide, silicon nitride, or silicon oxynitride.

The size or area of the inorganic insulating layer, for example, the second barrier layer 104, disposed on the uppermost layer of the substrate 100 may be less than the size or area of the first island portion 11 shown in FIG. 7. Referring to FIG. 8, the size or area of the inorganic insulating layer, for example, the second barrier layer 104, disposed on the uppermost layer of the substrate 100 may be less than the size or area of the first sub-substrate 101, the first barrier layer 102, and/or the second sub-substrate 103 of the substrate 100 corresponding to the first island portion 11.

A buffer layer 111 may be disposed on the substrate 100, and the first to third pixel driving circuits PC1, PC2, and PC3 may be disposed on the buffer layer 111. The buffer layer 111 may include an inorganic insulating material, such as silicon oxide, silicon nitride, or silicon oxynitride.

Each of the first to third pixel driving circuit portions PC1, PC2, and PC3 may include a transistor TFT. The transistor TFT may include a semiconductor layer Act, a gate electrode GE, a source electrode SE, and a drain electrode DE. FIG. 8 shows a top gate type in which the gate electrode GE is disposed on the semiconductor layer Act with a gate insulating layer 113 therebetween. However, according to another embodiment, the transistor TFT may be of a bottom gate type.

The semiconductor layer Act may include polysilicon. Alternatively, the semiconductor layer Act may include amorphous silicon, an oxide semiconductor, an organic semiconductor, or the like. The gate electrode GE may include a low-resistance metal material. The gate electrode GE may include a conductive material including molybdenum (Mo), aluminum (AI), copper (Cu), titanium (Ti), etc., and may be formed as a multi-layer or a single layer including the aforementioned material.

The gate insulating layer 113 between the semiconductor layer Act and the gate electrode GE may include an inorganic insulating material, such as silicon oxide, nitrogen oxide, silicon oxynitride, aluminum oxide, or titanium oxide. The gate insulating layer 113 may be a single layer or a multi-layer including the aforementioned material.

The source electrode SE and the drain electrode DE may be located on the same layer, for example, a second interlayer-insulating layer 117, and may include the same material. The source electrode SE and the drain electrode DE may each include a material with good conductivity. The source electrode SE and the drain electrode DE may each include a conductive material including Mo, Al, Cu, Ti, etc., and may be formed as a multi-layer or a single layer including the aforementioned material. In an embodiment, the source electrode SE and the drain electrode DE may each have a multi-layered structure including a titanium layer, an aluminum layer, and a titanium layer (Ti/Al/Ti). The second interlayer-insulating layer 117 may include an inorganic insulating material, such as silicon oxide, nitrogen oxide, silicon oxynitride, aluminum oxide, or titanium oxide, and may be a single layer or multi-layer including the aforementioned material.

The storage capacitor Cst may include a first electrode CE1 and a second electrode CE2 that overlap each other with a first interlayer-insulating layer 115 therebetween in a plan view. The storage capacitor Cst may overlap the transistor TFT in a plan view. In this regard, FIG. 15 shows that the gate electrode GE of the transistor TFT is the first electrode CE1 of the storage capacitor Cst. In another embodiment, the storage capacitor Cst may not overlap the transistor TFT in a plan view. The storage capacitor Cst may be covered with a second interlayer-insulating layer 207. The second electrode CE2 of the storage capacitor Cst may include a conductive material including Mo, Al, Cu, Ti, or the like and may be formed as a multi-layer or a single layer including the aforementioned material. The first interlayer-insulating layer 115 may be disposed between the gate insulating layer 113 and the second interlayer-insulating layer 117. The first interlayer-insulating layer 115 may include an inorganic insulating material, such as silicon oxide, nitrogen oxide, silicon oxynitride, aluminum oxide, or titanium oxide, and may be a single layer or multi-layer including the aforementioned material.

The size or area of the inorganic insulating material layer IOL corresponding to the first island portion 11 may be less than the size or area of the first island portion 11, as shown in FIG. 7. Referring to FIG. 8, the size or area of the inorganic insulating layer IOL disposed on the substrate 100 may be less than the size or area of the first sub-substrate 101, the first barrier layer 102, and/or the second sub-substrate 103 of the substrate 100. The inorganic insulating material layer IOL on the substrate 100 may include, for example, a buffer layer 111, a gate insulating layer 113, a first interlayer-insulating layer 115, and a second interlayer-insulating layer 117.

The edge of the inorganic insulating material layer IOL and the edge of the second sub-substrate 103 may overlap an organic material layer OL in a plan view. The organic material layer OL may define an opening therein corresponding to a central portion of the first island portion 11 and may have a type of frame shape extending along the edge of the first island portion 11. The organic material layer OL may cover the edge of the inorganic insulating layer IOL having a step with respect to the upper surface of the second sub-substrate 103, and the edge of the second sub-substrate 103. The organic material layer OL may include an organic insulating material, such as polyimide.

The first organic insulating layer 119 may be disposed on the second interlayer-insulating layer 117, and the second organic insulating layer 121 may be disposed on the first organic insulating layer 119. The first organic insulating layer 119 and the second organic insulating layer 121 may each include an organic insulating material, such as polyimide.

A second voltage line VSSL may be disposed on the second organic insulating layer 121, and a third organic insulating layer 123 may be disposed on the second organic insulating layer 121. The third organic insulating layer 123 may include an organic insulating material, such as polyimide. The second voltage line VSSL may include a conductive material including Mo, Al, Cu, Ti, or the like and may be formed as a multi-layer or a single layer including the aforementioned material.

A first electrode pad 241 and a second electrode pad 242 may be disposed on the third organic insulating layer 123. The first electrode pad 241 may be electrically connected to the transistor TFT through a first connection piece CM1 between the first organic insulating layer 119 and the second organic insulating layer 121 and a second connection piece CM2 between the second organic insulating layer 121 and the third organic insulating layer 123.

A light-emitting diode 230 may be disposed on the first electrode pad 241 and the second electrode pad 242 and may be electrically connected to the transistor TFT. As previously described, the light-emitting diode 230 may be an inorganic light-emitting diode and may include a first light-emitting diode 1230 that emits red light, a second light-emitting diode 2230 that emits green light, and a third light-emitting diode 3230 that emits blue light.

Each of the light-emitting diodes 230 may include a first semiconductor layer 231, a second semiconductor layer 232, an intermediate layer 233 between the first semiconductor layer 231 and the second semiconductor layer 232, a sub-pixel electrode 235 electrically connected to the first semiconductor layer 231, and an opposite electrode 238 electrically connected to the second semiconductor layer 232. The sub-pixel electrode 235 of the light-emitting diode 230 may be electrically connected to the first electrode pad 241, and the opposite electrode 238 may be electrically connected to the second electrode pad 242.

In addition, the sub-pixel electrode 235 may be electrically connected to the first semiconductor layer 231, and the opposite electrode 238 may be electrically connected to the second semiconductor layer 232. In an embodiment, the sub-pixel electrode 235 and the first semiconductor layer 231 may be connected to each other through a first bonding metal layer 236, and the opposite electrode 238 and the second semiconductor layer 232 may be connected to each other through a second bonding metal layer 237. The first bonding metal layer 236 and the second bonding metal layer 237 may each include a conductive material including Mo, Al, Cu, Ti, etc., and may be formed as a multi-layer or a single layer including the aforementioned material.

Specifically, the first light-emitting diode 1230 may include a first sub-pixel electrode 1235, a first opposite electrode 1238, a 1st-1 semiconductor layer 1231, a first intermediate layer 1233, and a 2nd-1 semiconductor layer 1232. The first sub-pixel electrode 1235 may be electrically connected to the first pixel driving circuit PC1, and the first opposite electrode 1238 may be electrically connected to the second voltage line VSSL. Likewise, the second light-emitting diode 2230 may include a second sub-pixel electrode 2235, a second opposite electrode 2238, a 1st-2 semiconductor layer 2231, a second intermediate layer 2233, and a 2nd-2 semiconductor layer 2232. The second sub-pixel electrode 2235 may be electrically connected to the second pixel driving circuit PC2, and the second opposite electrode 2238 may be electrically connected to the second voltage line VSSL. The third light-emitting diode 3230 may include a third sub-pixel electrode 3235, a third opposite electrode 3238, a 1st-3 semiconductor layer 3231, a third intermediate layer 3233, and a 2nd-3 semiconductor layer 3232. The third sub-pixel electrode 3235 may be electrically connected to the third pixel driving circuit PC3, and the third opposite electrode 3238 may be electrically connected to the second voltage line VSSL.

The sub-pixel electrode 235 may be disposed on the first electrode pad 241 and may include metal or metal oxide. The opposite electrode 238 may be disposed on the second electrode pad 242 and may include metal or metal oxide. For example, the sub-pixel electrode 235 and the opposite electrode 238 may each include Cu, gold (Au), chromium (Cr), Ti, Al, nickel (Ni), indium tin oxide (ITO), or oxide or alloy thereof. The sub-pixel electrode 235 and the opposite electrode 238 may be disposed on the same layer and include the same material. However, the disclosure is not limited thereto, and the sub-pixel electrode 235 and the opposite electrode 238 may include different materials in another embodiment.

The first semiconductor layer 231 may include a p-type semiconductor layer. The p-type semiconductor layer may include a semiconductor material having a composition formula of InₓAl_{y}Ga_{1-x-y}N (0≤x≤1, 0≤y≤1, and 0≤x+y≤1), such as GaN, AlN, AlGaN, InGaN, InN, InAlGaN, or AlInN, and may be doped with a p-type dopant, such as Mg, Zn, Ca, Sr, or Ba. For example, the first semiconductor layer 231 may include GaN doped with a p-type dopant.

The second semiconductor layer 232 may include an n-type semiconductor layer. The n-type semiconductor layer may include a semiconductor material having a composition formula of InₓAl_{y}Ga_{1-x-y}N (0≤x≤1, 0≤y≤1, and 0≤x+y≤1), such as GaN, AlN, AlGaN, InGaN, InN, InAlGaN, or AlInN, and may be doped with an n-type dopant, such as Si, Ge, and Sn. For example, the second semiconductor layer 232 may include GaN doped with an n-type dopant.

The intermediate layer 233 is a region where electrons and holes recombine. As the electrons and the holes recombine, the intermediate layer 233 may transition to a lower energy level and may generate light with a wavelength corresponding thereto. The intermediate layer 233 may also be referred to as an active layer. For example, the intermediate layer 233 may include a semiconductor material having a composition formula of InₓAl_{y}Ga_{1-x-y}N (0≤x≤1, 0≤y≤1, and 0≤x+y≤1), and may be formed to have a single quantum well structure or a multi quantum well (“MQW”) structure. The intermediate layer 233 may include a quantum dot structure or a quantum wire structure.

When the intermediate layer 233 includes a material having an MQW structure, the intermediate layer 233 may have a structure in which a plurality of quantum layers and a plurality of well layers are alternately stacked. Alternatively, the intermediate layer 233 may have a structure in which a semiconductor material with a large band gap energy and a semiconductor material with a small band gap energy are alternately stacked. The intermediate layer 233 may include different semiconductor materials depending on the wavelength of emitted light. In an embodiment, the intermediate layer 233 may emit blue light.

An encapsulation layer 300 may be disposed on the light-emitting diode 230 and may protect the light-emitting diode 230 from external force and/or moisture penetration. The encapsulation layer 300 may include an inorganic encapsulation layer and/or an organic encapsulation layer. In some embodiments, the encapsulation layer 300 may have a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material, such as resin. In some embodiments, the encapsulation layer 300 may include urethane epoxy acrylate. The encapsulation layer 300 may include a photosensitive material, such as photoresist.

A functional layer 400 may be disposed on the encapsulation layer 300. That is, the functional layer 400 may be disposed on the light-emitting diode 230. The functional layer 400 may include a light-blocking layer 410 and an overcoat layer 420.

The light-blocking layer 410 may define a light-blocking layer opening 410OP that overlaps the light-emitting diode 230 in a plan view. Because the light-blocking layer 410 defines a plurality of openings, the light-blocking layer 410 may have a grid shape or a mesh shape. The light-blocking layer 410 may include a light-blocking material and may include a black material. The light-blocking material may include carbon black, carbon nanotubes, a resin or paste including black dye, or metal particles. The metal particles may be, for example, nickel, aluminum, molybdenum, and/or alloys thereof. In addition, the light-blocking material may include metal oxide particles such as chromium oxide or metal nitride particles such as chromium nitride. As the light-blocking layer 410 includes a light-blocking material, reflection of external light by metal structures disposed below the light-blocking layer 410 may be reduced.

The overcoat layer 420 may be disposed on the light-blocking layer 410 to fill the openings of the light-blocking layer 410. The overcoat layer 420 may be formed integrally over the first to third sub-pixels SP1, SP2, and SP3. The overcoat layer 420 may be a colorless light-transmitting layer that does not have a color in the visible light band, and may flatten the upper surface of the functional layer 400. The overcoat layer 420 may include an organic material, such as acrylic, benzocyclobutene (“BCB”), or hexamethyldisiloxane (“HMDSO”).

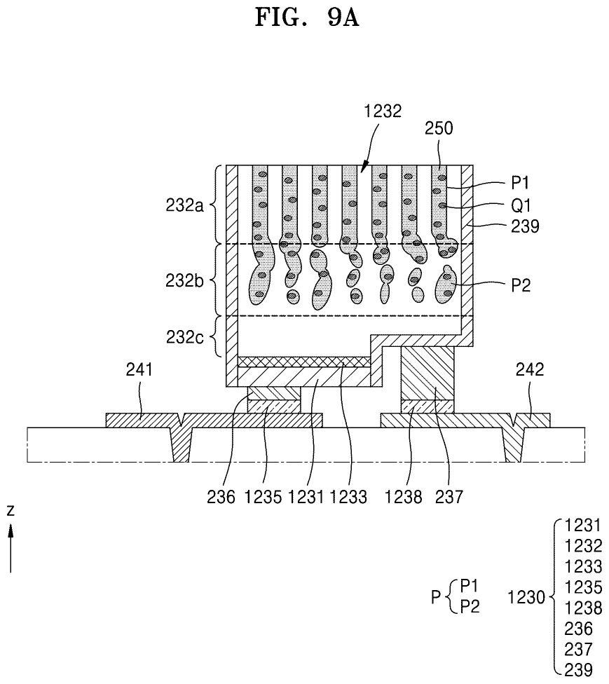

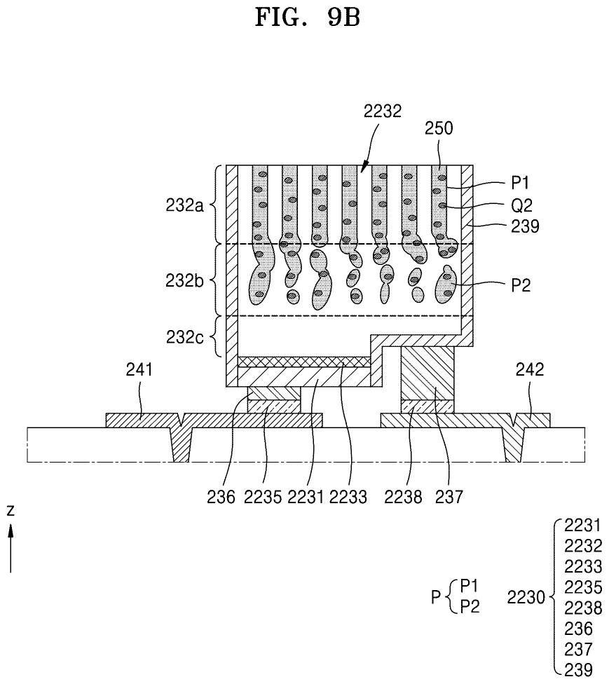

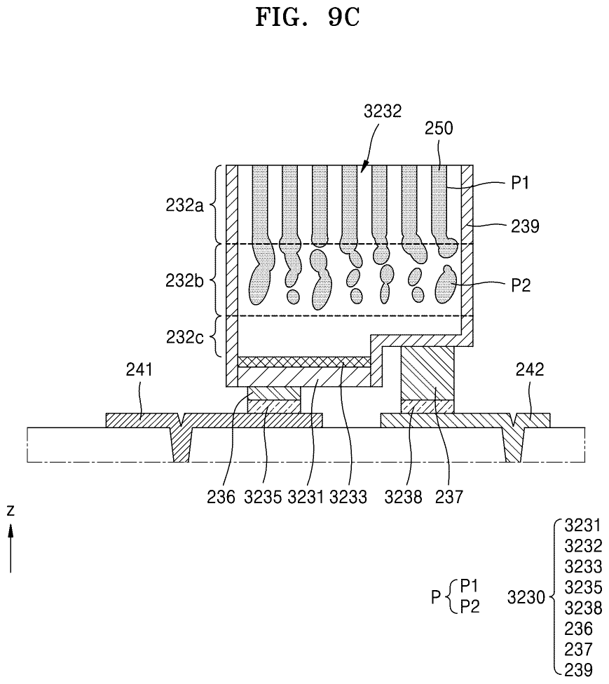

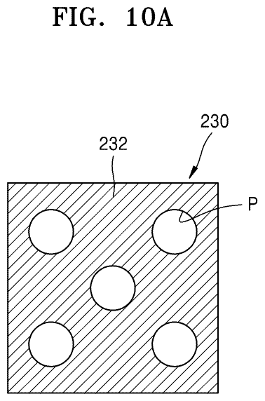

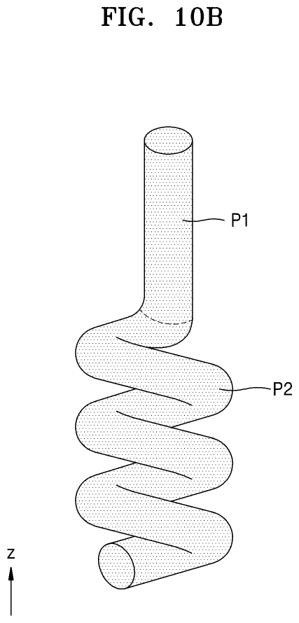

FIGS. 9A to 9C are cross-sectional views schematically showing a light-emitting diode of a display device according to an embodiment. FIG. 10A is a plan view schematically showing a pore structure of a display device according to an embodiment. FIG. 10B is a perspective view schematically showing a pore structure of a display device according to an embodiment.

FIG. 9A is an enlarged cross-sectional view of the first light-emitting diode 1230 of the first sub-pixel SP1 (see FIG. 7), FIG. 9B is an enlarged cross-sectional view of the second light-emitting diode 2230 of the second sub-pixel SP2 (see FIG. 7), and FIG. 9C is an enlarged cross-sectional view of the third light-emitting diode 3230 of the third sub-pixel SP3 (see FIG. 7).

First, referring to FIG. 9A, the first light-emitting diode 1230 may include a first sub-pixel electrode 1235, a 1st-1 semiconductor layer 1231, a first intermediate layer 1233, a 2nd-1 semiconductor layer 1232, and a first opposite electrode 1238.

As described above, the first sub-pixel electrode 1235 may be disposed on the first electrode pad 241 and electrically connected to the first pixel driving circuit portion PC1 (see FIG. 8), and the 1st-1 semiconductor layer 1231 may be electrically connected to the first sub-pixel electrode 1235 through the first bonding metal layer 236. The first opposite electrode 1238 may be disposed on the second electrode pad 242 and electrically connected to the second voltage line VSSL (see FIG. 8), and the 2nd-1 semiconductor layer 1232 may be electrically connected to the first opposite electrode 1238 through the second bonding metal layer 237.

The first intermediate layer 1233 may be disposed between the 1st-1 semiconductor layer 1231 and the 2nd-1 semiconductor layer 1232 and may emit light. In an embodiment, the first intermediate layer 1233 may have an MQW structure and may emit blue light.

The 2nd-1 semiconductor layer 1232 may have a porous structure in which a plurality of pores P are defined in a semiconductor material doped with an n-type dopant. The 2nd-1 semiconductor layer 1232 may have a double porous layer structure including a first porous layer 232a and a second porous layer 232b disposed below the first porous layer 232a. In an embodiment, the structures of pores P of the first porous layer 232a and the structures of pores P of the second porous layer 232b may be different from each other.

The first porous layer 232a may include a first pore P1 extending in a direction perpendicular to a major surface of the substrate 100, that is, in a third direction (e.g., z direction), and the second porous layer 232b may include a second pore P2 extending in a randomly variable direction. The major surface of the substrate 100 is parallel to the first direction (e.g., x direction) and the second direction (e.g., y direction).

The structure of the pore P will be described with reference to FIGS. 10A and 10B. First, referring to FIG. 10A, the 2nd-1 semiconductor layer 1232 may define a plurality of pores P therein. Although FIG. 10A shows that the 2nd-1 semiconductor layer 1232 defines 5 pores P therein, this is for convenience of explanation, and the 2nd-1 semiconductor layer 1232 may define a larger number of pores P therein in another embodiment.

The planar diameter of the pore P may have a size of about 100 nm to about 200 nm. As used herein, the “planar diameter” of the pore is a diameter of a cross section obtained by a plane perpendicular to the extending direction of the pore. In an embodiment, the first intermediate layer 1233 may emit blue light in a wavelength range of about 400 nm to about 495 nm. In this case, when the diameter of the pore P is greater than half the wavelength of light emitted from the first intermediate layer 1233, scattering of light may not occur easily, and thus, when the diameter of the pore P exceeds 200 nm, light extraction efficiency may decrease. Accordingly, the diameter of the pore P may be 200 nm or less. In addition, considering the size of quantum dots to be arranged in the pore P, which are to be described below, the diameter of the pore P may be 100 nm or more.

Referring to FIG. 10B, the pore P may include a first pore P1 of the first porous layer 232a and a second pore P2 of the second porous layer 232b. The first pore P1 may have a cylindrical shape extending in the third direction (e.g., z direction). That is, the first pore P1 may have a cylindrical hole structure passing through the first porous layer 232a. The second pore P2 may have a spiral cylindrical shape extending in a randomly variable direction. That is, the second pore P2 may have a spiral cylindrical shape passing through the second porous layer 232b. For example, the second pore P2 may have a spiral structure wound with a constant predetermined curvature, as shown in FIG. 10B. However, the structure of the second pore P2 is not limited thereto, and the second pore P2 may extend in a random direction and have a cylindrical shape wound with various curvatures. Additionally, the pore P may have a structure in which the first pore P1 and the second pore P2 are connected to each other and extend.

The pore P including the first pore P1 and the second pore P2 may have a thickness of about 2 μm to about 7 μm in the direction perpendicular to a major surface of the substrate 100 (see FIG. 8). In an embodiment, in the direction perpendicular to a major surface of the substrate 100 (see FIG. 8), the thickness of the first pore P1 and the thickness of the second pore P2 may be equal to each other. That is, in an embodiment, in the direction perpendicular to a major surface of the substrate 100 (see FIG. 8), the thickness of the first porous layer 232a and the thickness of the second porous layer 232b may be equal to each other.

The structure of the pore P may be formed by an electrochemical etching method. Nanoscale pores P may be defined in an n-type semiconductor layer, such as the 2nd-1 semiconductor layer 1232, by electrochemical etching, and the size, shape, and distribution of the pores P may be variously adjusted depending on the etchant, voltage, and/or doping concentration during the electrochemical etching process.

For example, when a sample such as a GaN epitaxial wafer is immersed in a certain solvent and then an external voltage is applied to the sample, the n-type semiconductor layer may be etched by generating carriers by an external bias. That is, when a voltage is applied to the sample, selective etching of the n-type semiconductor layer may occur under certain conditions and a porous layer may be formed. Specifically, when an electric field is applied in a direction perpendicular to a major surface of the substrate 100 (see FIG. 8), an electrolyte material penetrates the n-type semiconductor layer in a vertical direction according to the electric field, and thus, the pore P may be defined as a vertical cylindrical shape like the first pore P1. In addition, when the electric field applied in the vertical direction from the outside is released, the electrolyte material penetrates the n-type semiconductor layer in a random direction, and thus, the pore P may be defined as a cylindrical shape extending in a randomly variable direction like the second pore P2.

Through the etching process described above, the 2nd-1 semiconductor layer 1232 may have a double porous layer structure in which the pores P have different structures. That is, in the display device 1 according to an embodiment, as the n-type semiconductor layer includes the second porous layer 232b defining the second pores P2 therein in a random direction and the first porous layer 232a defining the first pores P1 therein in a vertical direction, the light extraction effect may be increased.

Specifically, light emitted from the first intermediate layer 1233 may be scattered through the second pores P2 of the second porous layer 232b in a random direction. That is, because an n-type semiconductor material (e.g., GaN) of the second porous layer 232b and a base resin 250, which will be described later, have different refractive indices and the second pores P2 are arranged to extend in various directions, light emitted from the first intermediate layer 1233 may be scattered more effectively. In an embodiment, as the second porous layer 232b serves to scatter light, the first light-emitting diode 1230 may not include additional scatterers.

In addition, because the first porous layer 232a defines the first pores P1 in the vertical direction therein, only vertical light of the light passing through the second porous layer 232b may be extracted from the first light-emitting diode 1230. That is, because the n-type semiconductor material of the first porous layer 232a and the base resin 250 have different refractive indices and the first pores P1 extend in the vertical direction, light passing through the second porous layer 232b may be emitted in the vertical direction. For example, of the light passing through the second porous layer 232b, light emitted in the vertical direction may be extracted in a vertical direction as is through the first pore P1. In addition, of the light passing through the second porous layer 232b, some of the light emitted in a lateral direction may be extracted in a direction close to the vertical through reflection at the interface of the first pore P1. In other words, the first pore P1 of the first porous layer 232a may increase the amount of light emitted in the vertical direction, and thus, the light extraction efficiency of the display device 1 may be effectively improved.

Referring back to FIG. 9A, a first quantum dot Q1 and the base resin 250 may be placed in the first pore P1 of the first porous layer 232a and the second pore P2 of the second porous layer 232b. The first quantum dot Q1 may be disposed in a dispersed form in the base resin 250 within the pore P and may be injected into the pore P. The first quantum dot Q1 and the base resin 250 may be injected through an inkjet process, a slit coating process, a spin coating process, or the like. The base resin 250 may be a light-transmitting material and may include a polymer resin, such as silicone resin, epoxy resin, acrylic, BCB, or HMDSO.

Quantum dots are inorganic materials with a size of several nanometers and have an energy bandgap of a certain wavelength, and thus, when the quantum dots absorb light with a higher energy than the energy bandgap, the quantum dots may emit light of a different wavelength. The quantum dots may control the color of emitted light depending on the particle size, and accordingly, the quantum dots may have various emission colors, such as blue, red, and green. In an embodiment, the first quantum dot Q1 arranged in the first sub-pixel SP1 may convert blue light emitted from the first intermediate layer 1233 into red light. The first quantum dot Q1 may absorb blue light and shift the wavelength thereof according to energy transition to emit red light. That is, the first porous layer 232a and the second porous layer 232b, which include first quantum dots Q1, may function as a color conversion layer that converts blue light into red light.

The first quantum dot Q1 may have a core-shell structure having a core portion and a shell portion, or may have a particle structure without a shell. The core-shell structure may be a single-shell structure or a multi-shell structure, for example, a double-shell structure. Quantum dots may include Group II-VI series semiconductors, Group III-V series semiconductors, Group IV-VI series semiconductors, Group IV series semiconductors, and/or graphene quantum dots. The first quantum dot Q1 may include, for example, Cd, Se, Zn, S and/or InP and may have a diameter of several tens of nm or less, for example, a diameter of about 10 nm or less.

As the first quantum dot Q1 as described above is arranged in the second pore P2 of the second porous layer 232b in a random direction, the color conversion efficiency of the first light-emitting diode 1230 may be effectively improved. That is, as the second pore P2 has a structure extending in a random direction, blue light whose color has not yet been converted may be scattered through the second pore P2 and converted into red light through the first quantum dot Q1.

In addition, as described above, the light converted to red light and scattered in the second porous layer 232b may be extracted as light in the vertical direction through the first porous layer 232a. However, because the first quantum dot Q1 is also arranged in the first porous layer 232a, blue light that has not yet been converted into red light in the second porous layer 232b may be converted into red light through the first quantum dot Q1 arranged in the first porous layer 232a. Accordingly, the display device 1 according to an embodiment may have excellent color conversion efficiency and light extraction efficiency. In an embodiment, as the color conversion efficiency within the light-emitting diode 230 (see FIG. 8) is excellent, an additional color filter layer may not be disposed on the light-emitting diode 230 (see FIG. 8).

The 2nd-1 semiconductor layer 1232 may further include a base layer 232c in addition to the first porous layer 232a and the second porous layer 232b. The base layer 232c may be a part of the 2nd-1 semiconductor layer 1232 that is in direct contact with the first intermediate layer 1233, and may be disposed between the first intermediate layer 1233 and the second porous layer 232b.

The base layer 232c may include a semiconductor material doped with an n-type dopant, similar to the first porous layer 232a and the second porous layer 232b. For example, the base layer 232c may include GaN doped with an n-type dopant. However, the base layer 232c may include a non-porous structure, unlike the first porous layer 232a and the second porous layer 232b. That is, the base layer 232c may be a 2nd-1 semiconductor layer 1232 in which no pores P are arranged. The reason why the pores P is not arranged in the base layer 232c may be to increase the luminous efficiency of the first intermediate layer 1233. The base layer 232c may have a thickness of about 0.3 μm to about 0.5 μm in the direction perpendicular to a major surface of the substrate 100 (see FIG. 8).

The first light-emitting diode 1230 may further include a protective layer 239. The protective layer 239 may be disposed on the side of the first light-emitting diode 1230. Specifically, the protective layer 239 may cover opposite sides of the 1st-1 semiconductor layer 1231, opposite sides of the first intermediate layer 1233, and opposite sides of the 2nd-1 semiconductor layer 1232. The protective layer 239 may be provided as a single layer or a multi-layer. When the protective layer 239 is provided as a multi-layer, the protective layer 239 may have a distributed Bragg reflector (“DBR”) structure in which a first layer and a second layer, which include an inorganic film and have different refractive indices, are alternately stacked.

Next, referring to FIG. 9B, the second light-emitting diode 2230 may have the same structure as the first light-emitting diode 1230 but may include a second quantum dot Q2 instead of the first quantum dot Q1. As previously described, quantum dots may control the color of emitted light depending on the particle size, and accordingly, quantum dots may have various emission colors, such as blue, red, and green. In an embodiment, the second quantum dot Q2 arranged in the second sub-pixel SP2 may convert blue light emitted from the first intermediate layer 1233 into green light. The second quantum dot Q2 may absorb blue light and shift the wavelength thereof according to energy transition to emit green light. That is, the first porous layer 232a and the second porous layer 232b, which include second quantum dots Q2, may function as a color conversion layer that converts blue light into green light.

In addition, because the 2nd-2 semiconductor layer 2232 also has a double porous layer structure including the first porous layer 232a and the second porous layer 232b, the second light-emitting diode 2230 may have excellent color conversion efficiency and light extraction efficiency like the first light-emitting diode 1230.

Next, referring to FIG. 9C, quantum dots may not be arranged in the pore P of the third light-emitting diode 3230, and only the base resin 250 may fill the pore P. Specifically, the third sub-pixel SP3 may be a sub-pixel that emits blue light, and because the third intermediate layer 3233 already emits blue light, a color conversion process may not be necessary. Accordingly, quantum dots may not be arranged in the 2nd-3 semiconductor layer 3232 of the third light-emitting diode 3230, and thus, the first porous layer 232a and the second porous layer 232b may function as a light-transmitting layer.

However, even when quantum dots are not arranged in the third light-emitting diode 3230, the first porous layer 323a of the third light-emitting diode may have a first pore P1 in a first vertical direction, and the second porous layer 232b may have a second pore P2 in a random direction. That is, because the 2nd-3 semiconductor layer 3232 also has a double porous layer structure including the first porous layer 232a and the second porous layer 232b, the third light-emitting diode 3230 may have excellent light extraction efficiency like the first light-emitting diode 1230.

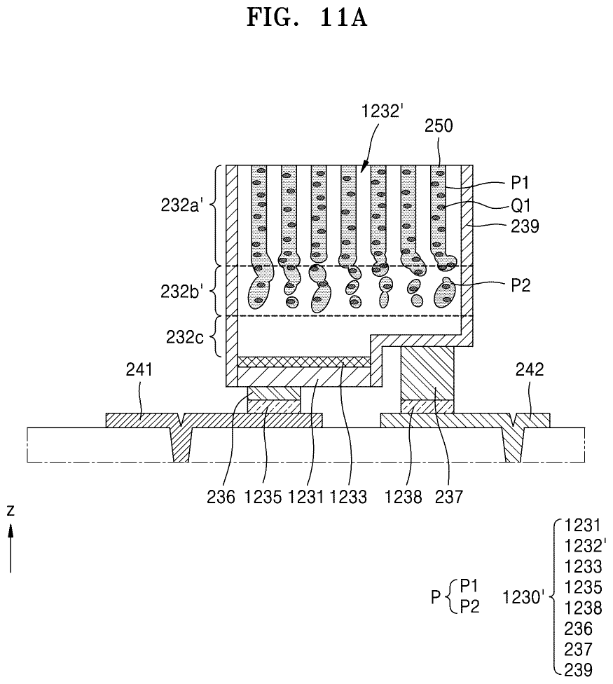

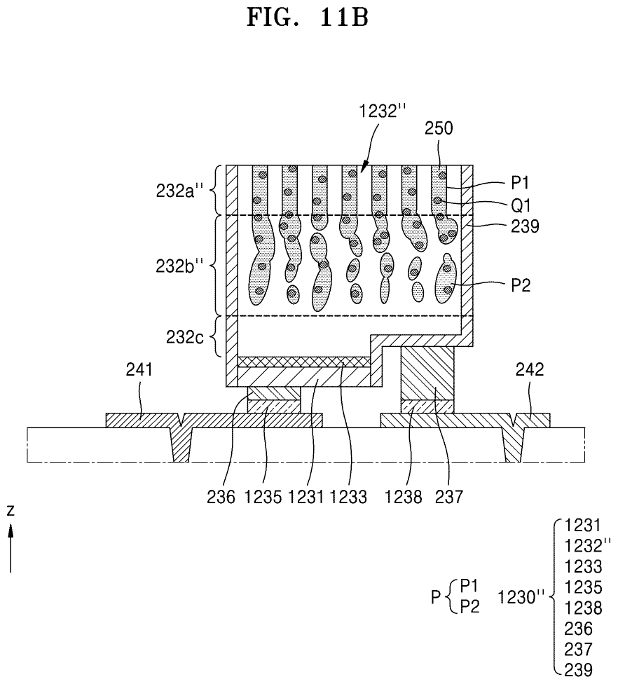

FIG. 11A is a cross-sectional view schematically showing a light-emitting diode of a display device according to another embodiment. FIG. 11B is a cross-sectional view schematically showing a light-emitting diode of a display device according to another embodiment. Referring to FIGS. 11A and 11B, except for the features of the first porous layer 232a and the second porous layer 232b, other features are the same as those described with reference to FIGS. 7 to 10B. In FIGS. 11A and 11B, the same reference numerals as those in FIGS. 7 to 10B denote the same members as those in FIGS. 7 to 10B, and thus, redundant descriptions thereof are omitted and the differences will be described below.

First, referring to FIG. 11A, a first light-emitting diode 1230′ may include a 1st-1 semiconductor layer 1231, a first intermediate layer 1233, and a 2nd-1 semiconductor layer 1232′. The 2nd-1 semiconductor layer 1232′ may include a first porous layer 232a′, a second porous layer 232b′, and a base layer 232c.

However, in an embodiment, the thickness of a first pore P1 may be greater than the thickness of a second pore P2 in a third direction (e.g., z direction). That is, in a direction perpendicular to a major surface of the substrate 100 (FIG. 8), the thickness of the first porous layer 232a′ may be greater than the thickness of the second porous layer 232b′. Accordingly, because the length of the first pore P1 extending in a vertical direction (e.g., z direction) is increased, the amount of light, which is extracted in the vertical direction, of the light emitted from the first intermediate layer 1233 may increase. As a result, the display device according to the embodiment shown in FIG. 11A may effectively improve light extraction efficiency. The structure shown in FIG. 11A is not only applied to the first light-emitting diode 1230′, but may also be applied to the second light-emitting diode 2230 (see FIG. 8) and the third light-emitting diode 3230 (see FIG. 8).

Next, referring to FIG. 11B, a first light-emitting diode 1230″ may include a 1st-1 semiconductor layer 1231, a first intermediate layer 1233, and a 2nd-1 semiconductor layer 1232″. The 2nd-1 semiconductor layer 1232″ may include a first porous layer 232a″, a second porous layer 232b″, and a base layer 232c.

However, in an embodiment, the thickness of a second pore P2 may be greater than the thickness of a first pore P1 in a third direction (e.g., z direction). That is, in a direction perpendicular to a major surface of the substrate 100 (see FIG. 8), the thickness of the second porous layer 232b″ may be greater than the thickness of the first porous layer 232a″. Accordingly, because the length of the second pore P2 extending in a random direction is increased, the scattering rate of light emitted from the first intermediate layer 1233 may increase. When the scattering rate increases, light, which has not yet been converted, of the blue light emitted from the first intermediate layer 1233 may be scattered and converted into red light through first quantum dots Q1. As a result, the display device according to the embodiment shown in FIG. 11B may effectively improve color conversion efficiency. The structure shown in FIG. 11B is not only applied to the first light-emitting diode 1230″, but may also be applied to the second light-emitting diode 2230 (see FIG. 8) (see FIG. 8).

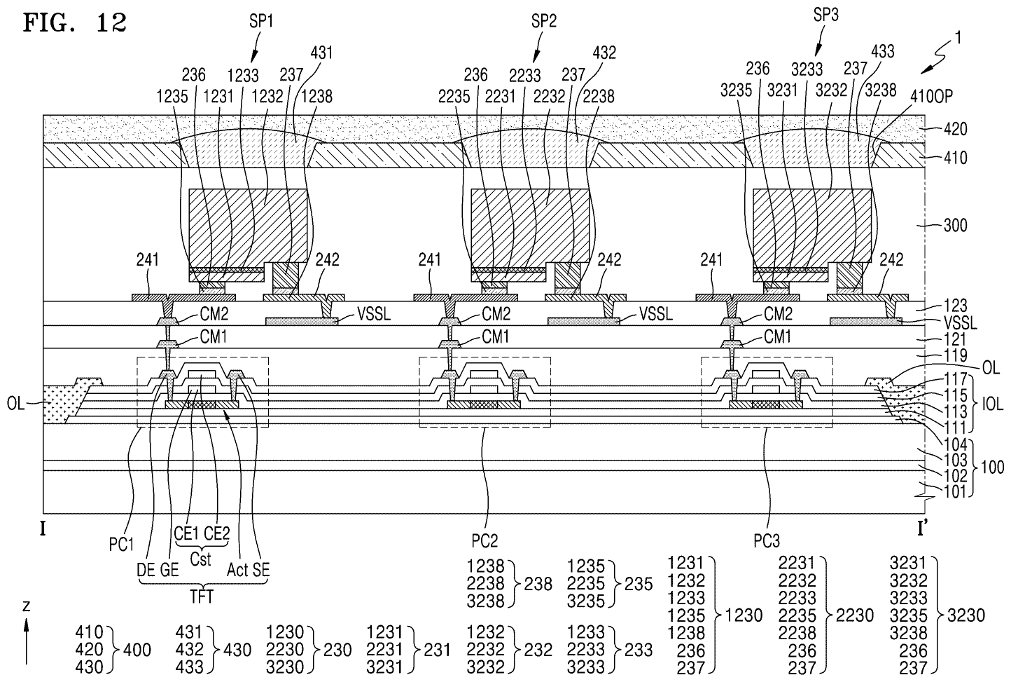

FIG. 12 is a cross-sectional view schematically showing a portion of a display device according to another embodiment. Referring to FIG. 12, except for the features of the functional layer 400, other features are the same as those described with reference to FIGS. 7 to 10B. In FIG. 12, the same reference numerals as those in FIGS. 7 to 10B denote the same members as those in FIGS. 7 to 10B, and thus, redundant descriptions thereof are omitted and the differences will be described below.

Referring to FIG. 12, a functional layer 400 may further include a color filter layer 430 in addition to the light-blocking layer 410 and the overcoat layer 420. The color filter layer 430 may include first to third color filters 431, 432, and 433 corresponding to the first to third sub-pixels SP1, SP2, and SP3, respectively. The first to third color filters 431, 432, and 433 may overlap the first to third light-emitting diodes 1230, 2230, and 3230, respectively, in a direction perpendicular to a major surface of the substrate 100. The first to third color filters 431, 432, and 433 may filter light emitted from the first to third light-emitting diodes 1230, 2230, and 3230, respectively.

The first color filter 431 may pass only red light in the wavelength range of about 580 nm to about 780 nm, the second color filter 432 may pass only green light in the wavelength range of about 495 nm to about 580 nm, and the third color filter 433 may pass only blue light in the wavelength range of about 400 nm to about 495 nm. Accordingly, the color filter layer 430 may increase the color purity of light by passing only light in a certain wavelength band, of the light emitted from the light-emitting diode 230.

In addition, the color filter layer 430 may reduce external light reflection in the display device 1. For example, when external light reaches the first color filter 431, only light with a preset wavelength as described above may pass through the first color filter 431 and light with other wavelengths may be absorbed by the first color filter 431. Therefore, of the external light incident on the display device 1, only light with a preset wavelength as described above may pass through the first color filter 431 and some of the light may be reflected from the opposite electrode 238 or the sub-pixel electrode 235 below the first color filter 431 and be emitted to the outside again. As a result, because only some of the external light incident on the location where the first sub-pixel SP1 is located is reflected to the outside, external light reflection may be reduced. This description may be equally applied to the second color filter 432 and the third color filter 433.

That is, in the display device 1 according to the embodiment as shown in FIG. 12, as the light-emitting diode 230 includes a double porous layer structure and quantum dots, color conversion efficiency and light extraction efficiency may be primarily improved. In addition, as the functional layer 400 includes the color filter layer 430, color conversion efficiency may be secondarily improved and external light reflection may be reduced. As a result, the display device 1 according to another embodiment may implement images with better quality.

According to embodiments of the disclosure, a display device that may implement images with excellent quality by improving light conversion efficiency and light extraction efficiency may be provided. The aforementioned effects are exemplary, and the scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a substrate including a display area and a non-display area outside the display area; and
a plurality of light-emitting diodes arranged in the display area,
wherein each of the plurality of light-emitting diodes has a double porous layer structure including a first porous layer and a second porous layer disposed below the first porous layer, the first porous layer defines a first pore therein extending in a direction perpendicular to a major surface of the substrate, and the second porous layer defines a second pore therein extending in a randomly variable direction.

2. The display device of claim 1, wherein quantum dots are arranged within the first pore and the second pore.

3. The display device of claim 2, further comprising a base resin arranged in the first pore and the second pore,
wherein the quantum dots are dispersedly arranged in the base resin.

4. The display device of claim 3, wherein the display area includes a first sub-pixel for emitting red light, a second sub-pixel for emitting green light, and a third sub-pixel for emitting blue light, the quantum dots are arranged in a light-emitting diode of the first sub-pixel and a light-emitting diode of the second sub-pixel, and the plurality of light-emitting diodes includes the light-emitting diode of the first sub-pixel and the light-emitting diode of the second sub-pixel.

5. The display device of claim 4, wherein the first pore and the second pore arranged in the third sub-pixel are filled with the base resin without the quantum dots.

6. The display device of claim 1, wherein the first pore and the second pore are extended and connected to each other.

7. The display device of claim 1, wherein the first pore has a cylindrical shape.

8. The display device of claim 1, wherein the second pore has a spiral cylindrical shape.

9. The display device of claim 1, wherein a planar diameter of each of the first pore and the second pore is about 100 nanometers (nm) to about 200 nm.

10. The display device of claim 1, wherein, in the direction perpendicular to the major surface of the substrate, a thickness of the first porous layer and a thickness of the second porous layer are equal to each other.

11. The display device of claim 1, wherein, in the direction perpendicular to the major surface of the substrate, a thickness of the first porous layer is greater than a thickness of the second porous layer.

12. The display device of claim 1, wherein, in the direction perpendicular to the major surface of the substrate, a thickness of the second porous layer is greater than a thickness of the first porous layer.

13. The display device of claim 1, wherein each of the plurality of light-emitting diodes further includes:
a first semiconductor layer doped with a p-type dopant;
a second semiconductor layer doped with an n-type dopant; and
an intermediate layer disposed between the first semiconductor layer and the second semiconductor layer,
wherein the first porous layer and the second porous layer are included in the second semiconductor layer.

14. The display device of claim 13, wherein the first porous layer has a structure in which the first pore is defined in a material constituting the second semiconductor layer, and the second porous layer has a structure in which the second pore is defined in a material constituting the second semiconductor layer.

15. The display device of claim 14, wherein the material constituting the second semiconductor layer includes a semiconductor material having a composition formula InₓAl_{y}Ga_{1-x-y}N, where O≤x≤1, 0≤y≤1, and 0≤x+y≤1.

16. The display device of claim 13, wherein the second semiconductor layer further includes a base layer disposed between the intermediate layer and the second porous layer,
wherein the base layer has a non-porous structure.

17. The display device of claim 16, wherein each of the first porous layer and the second porous layer has a thickness of about 2 micrometers (μm) to about 7 μm.

18. The display device of claim 16, wherein the base layer has a thickness of about 0.3 μm to about 0.5 μm.

19. The display device of claim 13, wherein each of the plurality of light-emitting diodes further includes:
a sub-pixel electrode electrically connected to the first semiconductor layer; and
an opposite electrode electrically connected to the second semiconductor layer,
wherein the sub-pixel electrode is connected to a pixel circuit arranged in the display area, and the opposite electrode is electrically connected to a voltage line for receiving a low-potential voltage.

20. The display device of claim 1, further comprising:
a light-blocking layer disposed above each of the plurality of light-emitting diodes and defining a light-blocking layer opening therein overlapping the light-emitting diode; and
an overcoat layer disposed on the light-blocking layer.

21. The display device of claim 20, wherein the overcoat layer fills the light-blocking layer opening.

22. The display device of claim 20, further comprising a color filter layer, which fills the light-blocking layer opening,
wherein the overcoat layer covers the light-blocking layer and the color filter layer.

23. The display device of claim 20, further comprising an encapsulation layer disposed between the light-blocking layer and each of the plurality of light-emitting diodes.

24. The display device of claim 1, further comprising:
island portions arranged in the display area and spaced apart from each other along rows and columns; and
bridge portions connecting adjacent island portions among the island portions to each other,
wherein each of the island portions includes at least one light-emitting diode of the plurality of light-emitting diodes.

25. The display device of claim 24, wherein the bridge portions each have a serpentine shape.
